(19) United States
(12) Patent Application Publication
(10) Pub. No.: US 2013/0228867 A1
(43) Pub. Date: Sep. 5, 2013

(54) SEMICONDUCTOR DEVICE PROTECTED FROM ELECTROSTATIC DISCHARGE

(71) Applicant: KABUSHIKI KAISHA TOSHIBA, Tokyo (JP)

(72) Inventors: Yasuhiro Suematsu, Yokohama-shi (JP); Masaru Koyanagi, Tokyo (JP); Mikihiko Ito, Tokyo (JP)

(73) Assignee: KABUSHIKI KAISHA TOSHIBA, Tokyo (JP)

(21) Appl. No.: 13/782,485

(22) Filed: Mar. 1, 2013

(30) Foreign Application Priority Data
Mar. 2, 2012 (JP) 2012-046627
Nov. 20, 2012 (JP) 2012-254753

(51) Int. Cl. H01L 23/60

(52) U.S. Cl. CPC H01L 23/60
USPC 257/355

(57) ABSTRACT

According to one embodiment, a semiconductor device includes a first semiconductor chip, at least one second semiconductor chip, a first connector, and a second connector. The first semiconductor chip includes a first input pad, first protection circuit, and first internal circuit. The at least one second semiconductor chip includes a second input pad, second protection circuit, and second internal circuit. The first connector electrically connects the first and second input pads. The second connector connects the first protection circuit and first input pad of the first semiconductor chip. The second protection circuit of the at least one second semiconductor chip is not connected to the second input pad.

### CROSS-REFERENCE TO RELATED APPLICATIONS

This application is based upon and claims the benefit of priority from Japanese Patent Applications No. 2012-046627, filed Mar. 2, 2012; and No. 2012-254753, filed Nov. 20, 2012, the entire contents of all of which are incorporated herein by reference.

### FIELD

Embodiments described herein relate generally to a semiconductor device and, more particularly, to the protection of a semiconductor chip or a package incorporating a semiconductor chip from electrostatic discharge (ESD).

### BACKGROUND

In a semiconductor device, a protection circuit including a protection element is connected to a pad of a semiconductor chip in order to protect an internal circuit from ESD. Recently, as the capacity of a semiconductor device increases, a technique of stacking a plurality of chips in one package has been developed. When stacking a plurality of chips, pads having the same function in the individual chips are connected to each other and connected to an input pin of a package. Therefore, the capacitances of protection elements connected to the pads of a plurality of chips are connected to the same pin. When a plurality of capacitances are thus connected to the same pin, the signal propagation speed decreases, and this makes a high-speed operation difficult to perform.

### BRIEF DESCRIPTION OF THE DRAWINGS

FIGS. 1A, 1B, and 1C are schematic views showing a semiconductor device according to the first embodiment, in which FIG. 1A is a side view showing stacked chips, FIG. 1B is a circuit diagram showing a part of a first semiconductor chip, and FIG. 1C is a circuit diagram showing a part of a second semiconductor chip;

FIGS. 2A, 2B, and 2C are views showing details of portions of the first embodiment, in which FIG. 2A is a side view showing the stacked chips, FIG. 2B is a circuit diagram showing a part of the first semiconductor chip, and FIG. 2C is a circuit diagram showing a part of the second semiconductor chip;

FIGS. 3A, 3B, and 3C are schematic views showing a semiconductor device according to the second embodiment, in which FIG. 3A is a side view showing stacked chips, FIG. 3B is a circuit diagram showing a part of a first semiconductor chip, and FIG. 3C is a circuit diagram showing a part of a second semiconductor chip;

FIG. 4 is an exemplary sectional view showing a semiconductor device according to the third embodiment;

FIGS. 5A, 5B, and 5C are schematic views showing a semiconductor device according to the fourth embodiment, in which FIG. 5A is a side view showing stacked chips, FIG. 5B is a circuit diagram showing a part of a semiconductor chip dedicated for an ESD protection circuit, and FIG. 5C is a circuit diagram showing a part of a semiconductor chip;

FIGS. 6A, 6B, and 6C are schematic views showing a semiconductor device according to the fifth embodiment, in which FIG. 6A is a side view showing stacked chips, FIG. 6B is a circuit diagram showing a part of a controller chip, and FIG. 6C is a circuit diagram showing a part of a semiconductor chip;

FIG. 7 is a block diagram showing an example of the arrangement of a NAND flash memory;

FIG. 8 is a circuit diagram showing an example of the circuit configuration of a memory cell array;

FIG. 9 is a block diagram showing an example of a buffer according to the sixth embodiment;

FIG. 10 is a circuit diagram showing an example of a buffer unit according to the sixth embodiment;

FIG. 11 is a view showing an example of the layout of transistors arranged in an output buffer circuit;

FIG. 12 is a circuit diagram showing an example of the first modification of the buffer unit;

FIG. 13 is a circuit diagram showing an example of the second modification of the buffer unit;

FIG. 14 is a view showing an example of a semiconductor device according to the seventh embodiment;

FIG. 15 is a circuit diagram showing an example of a buffer unit of a second semiconductor chip according to the seventh embodiment;

FIG. 16 is a circuit diagram showing an example of a modification of the buffer unit of the second semiconductor chip according to the seventh embodiment;

FIG. 17 is a view showing an example of the first modification of the semiconductor device according to the seventh embodiment;

FIG. 18 is a view showing an example of a semiconductor device according to the eighth embodiment;

FIG. 19 is a view showing an example of the first modification of the semiconductor device according to the eighth embodiment; and

FIG. 20 is a view showing an example of a semiconductor device according to the ninth embodiment.

### DETAILED DESCRIPTION

In general, according to one embodiment, a semiconductor device includes a first semiconductor chip, at least one second semiconductor chip, a first connector, and a second connector. The first semiconductor chip includes a first input pad, first protection circuit, and first internal circuit, the first input pad is connected to the first internal circuit and receives an external signal, and the first protection circuit protects the first internal circuit. The at least one second semiconductor chip includes a second input pad, second protection circuit, and second internal circuit, the second input pad is connected to the second internal circuit and receives the external signal, and the second protection circuit protects the second internal circuit. The first connector electrically connects the first and second input pads. The second connector connects the first protection circuit and first input pad of the first semiconductor chip. The second protection circuit of the at least one second semiconductor chip is not connected to the second input pad.

Embodiments will be explained below with reference to the accompanying drawings.

### First Embodiment

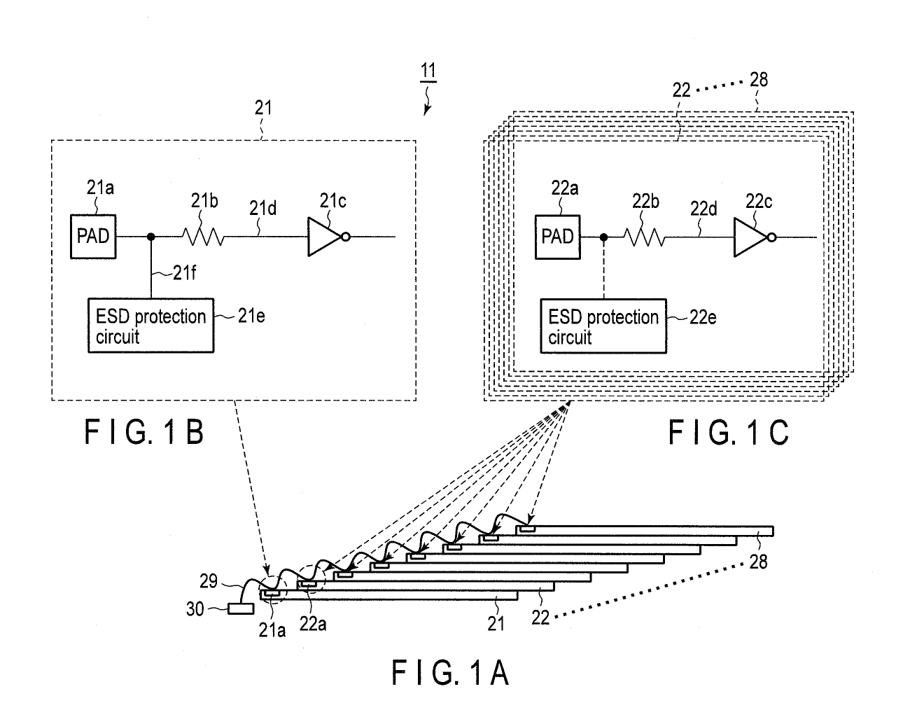

FIGS. 1A, 1B, and 1C show a semiconductor device according to the first embodiment.

In a semiconductor device 11 as shown in FIG. 1A, a first semiconductor chip 21 placed on a base (not shown) and a plurality of second semiconductor chips 22 to 28 are stacked as they are shifted from each other at a predetermined interval. The base has an input pin connection pad 30 to be connected to an input pin. The first semiconductor chip 21 and the plurality of second semiconductor chips 22 to 28 have almost the same arrangement, and each of them is formed by, e.g., a NAND flash memory (not shown). Also, the first semiconductor chip 21 of the plurality of semiconductor chips is formed in the lowermost layer.

FIG. 1B shows an arrangement pertaining to one input pad formed in the first semiconductor chip 21. Referring to FIG. 1B, an input pad 21a is connected to the input terminal of an input buffer 21c via a protection resistance 21b. The output terminal of the input buffer 21c is connected to an internal circuit (not shown). The protection resistance 21b is the wiring resistance of a metal interconnection 21d formed in, e.g., the lowermost layer of a plurality of metal interconnection layers (not shown) formed in the first semiconductor chip 21, and has a resistance value of, e.g., about 300 Ω.

An ESD protection circuit 21e is connected to the input pad 21a. The ESD protection circuit 21e includes a P-channel MOS transistor (to be referred to as a PMOS transistor hereinafter) connected between the input pad 21a and a power supply, and an N-channel MOS transistor (to be referred to as an NMOS transistor hereinafter) connected between the input pad 21a and ground (see an ESD protection circuit 69d to be described later). The ESD protection circuit 21e is connected to the input pad 21a by a metal interconnection 21f formed in, e.g., the uppermost layer of the first semiconductor chip 21.

On the other hand, FIG. 1C shows only the second semiconductor chip 22 as an example of the arrangement of the second semiconductor chips 22 to 28, i.e., shows an arrangement related to one input pad of the second semiconductor chip 22. The second semiconductor chips 23 to 28 have the same arrangement as that of the second semiconductor chip 22.

Referring to FIG. 1C, an input buffer 22c is connected to an input pad 22a via a protection resistance 22b. The protection resistance 22b is the wiring resistance of a metal interconnection 22d formed in, e.g., the lowermost layer of a plurality of metal interconnection layers (not shown) formed in the upper portion of the second semiconductor chip 22, and has a resistance value of, e.g., about 300 Ω.

In addition, an ESD protection circuit 22e is formed in the second semiconductor chip 22 as in the first semiconductor chip 21. However, the ESD protection circuit 22e is not connected to the input pad 22a. That is, the ESD protection circuit 22e is formed in the second semiconductor chip 22, but has no protecting function for the second semiconductor chip 22.

As in the second semiconductor chip 22, ESD protection circuits 22e of the second semiconductor chips 23 to 28 are not connected to input pads 22a, and have no protecting function.

As shown in FIG. 1A, the first semiconductor chip 21 and second semiconductor chips 22 to 28 having the above arrangements are stacked as they are shifted from each other at a predetermined interval, thereby exposing the input pads 21a and 22a. A bonding wire 29 is continuously sequentially bonded to the exposed input pad 21a and the plurality of exposed input pads 22a.

That is, the bonding wire 29 is first bonded to the input pad 30 which is formed on the base (not shown) and to which the input pin is connected. The input pad 30 connects the stacked first and second semiconductor chips 21 and 22 to 28 and an external circuit.

Then, the bonding wire 29 bonded to the input pad 30 is bonded to the input pad 21a of the first semiconductor chip 21, and bonded to the input pads 22a of the second semiconductor chips 22 to 28. Thus, the input pad 30, the input pad 21a, and the plurality of input pads 22a are electrically connected.

In the state in which the bonding wire 29 is connected to the input pad 21a of the first semiconductor chip 21 and to the plurality of input pads 22a of the second semiconductor chips 22 to 28 as described above, only the ESD protection circuit 21e of the first semiconductor chip 21 is connected to the bonding wire 29 and input pad 30. This makes it possible to reduce the capacitance connected to the bonding wire 29 and input pad 30, and prevent a decrease in signal propagation speed.

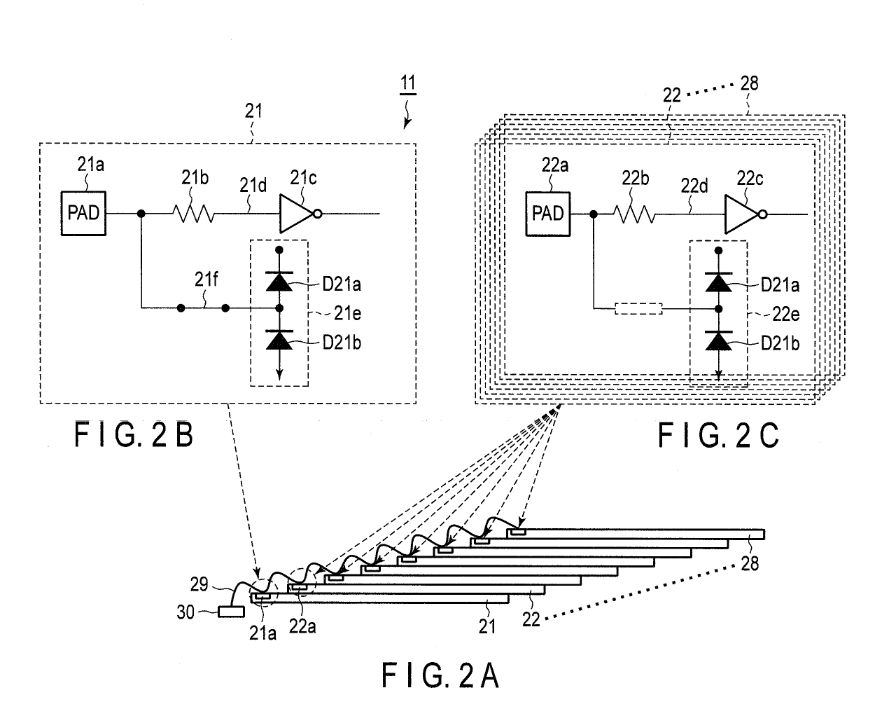

FIGS. 2A, 2B, and 2C show details of portions of FIGS. 1A, 1B, and 1C. The same reference numerals as in FIGS. 1A, 1B, and 1C denote the same parts in FIGS. 2A, 2B, and 2C. Referring to FIGS. 2B and 2C, the circuits of the ESD protection circuits 21e and 22e are indicated by diodes D21a, D21b, D22a, and D22b instead of the PMOS transistor and NMOS transistor.

In the first semiconductor chip 21, the ESD protection circuit 21e is formed in a semiconductor substrate (not shown), and the input pad 21a is formed on the surface of the semiconductor substrate. The input pad 21a and ESD protection circuit 21e are connected, via a contact (not shown), by the uppermost metal interconnection 21f of a plurality of metal interconnection layers formed above the semiconductor substrate.

In the second semiconductor chip 22, the ESD protection circuit 22e is formed in a semiconductor substrate (not shown), and the input pad 22a is formed on the surface of the semiconductor substrate. The input pad 22a and ESD protection circuit 22e are not electrically connected. Accordingly, the ESD protection circuit 22e is set in an unfunctional state.

As described above, the first semiconductor chip 21 and second semiconductor chip 22 have the same arrangement except for the uppermost metal interconnection patterns. Therefore, these semiconductor chips can easily be manufactured by changing masks for forming the uppermost metal interconnections. It is also possible to form the uppermost interconnection pattern by cutting the metal interconnection by using a laser or the like.

The arrangement corresponding to one input pad formed in each of the first and second semiconductor chips 21 and 22 to 28 has been explained with reference to FIGS. 1A, 1B, and 10 and FIGS. 2A, 2B, and 2C. However, the first embodiment is not limited to this, and the first embodiment is also applicable to an output pad or input/output pad.

### (Effects)

According to the first embodiment described above, the first semiconductor chip 21 includes the ESD protection circuit 21e, the plurality of second semiconductor chips 22 to 28 each include the ESD protection circuit 22e, the ESD protection circuit 21e of the first semiconductor chip 21 is connected to the input pad 21a, and the ESD protection circuit 22e of each of the second semiconductor chips 22 to 28 is not connected to the input pad 22a. Therefore, in the state in which the bonding wire 29 is connected from the input pad 30 to the input pad 21a of the first semiconductor chip 21 and to the plurality of input pads 22a of the second semiconductor chips 22 to 28, only the ESD protection circuit 21e of the first semiconductor chip 21 is connected to the bonding wire 29 and input pad 30. This makes it possible to reduce the capacitance connected to the bonding wire 29 and input pad 30, and prevent a decrease in signal propagation speed.

Also, the first and second semiconductor chips 21 and 22 have the same arrangement except for the uppermost metal interconnection patterns. Accordingly, the first and second semiconductor chips 21 and 22 can be manufactured by the same steps before the formation of the uppermost metal interconnections, and can be manufactured by changing only masks for forming the uppermost metal interconnections. This facilitates the manufacture because most manufacturing steps are common.

Furthermore, the input pad 30 to which the input pin is connected, the input pad 21a, and the plurality of input pads 22a are connected in this order by wire bonding. That is, the ESD protection circuit 21e of the first semiconductor chip 21 positioned close to the input pad is set in a functional state. On the other hand, in the second semiconductor chip 22 beyond the ESD protection circuit 21e of the first semiconductor chip 21, the ESD protection circuit 22e is set in an unfunctional state. That is, the first semiconductor chip 21 to which ESD is most strongly applied is strongly protected against ESD, and the second semiconductor chip 22 to which ESD is not strongly applied is weakly protected against ESD. Consequently, it is possible to provide a semiconductor device having sufficient protection against ESD, and capable of a high-speed operation by preventing a decrease in signal propagation speed caused by the protection circuit.

### Second Embodiment

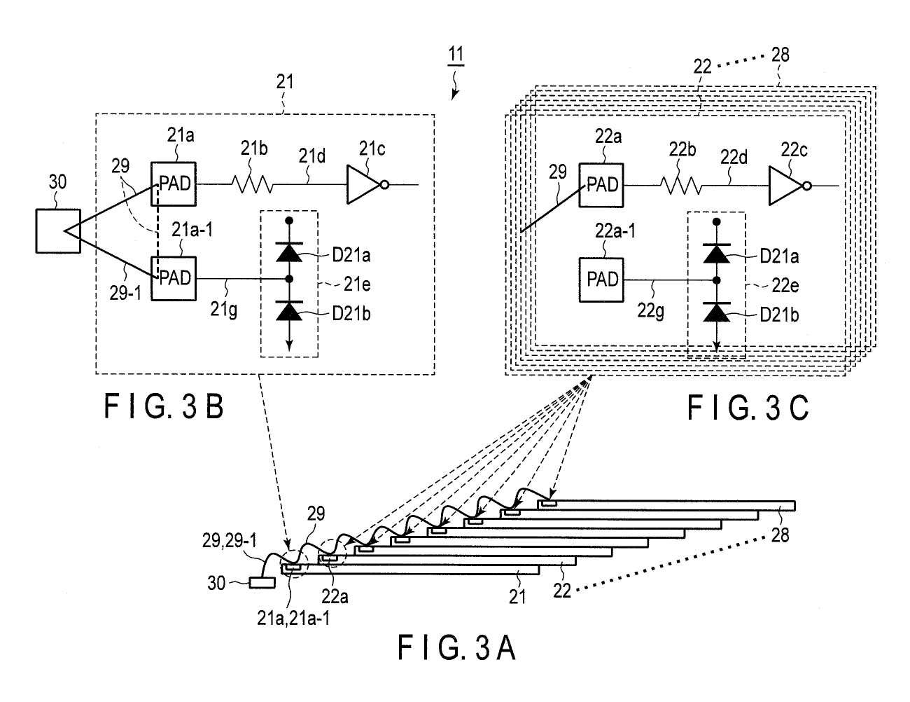

FIGS. 3A, 3B, and 3C show the second embodiment. The same reference numerals as in FIGS. 2A, 2B, and 2C denote the same parts in FIGS. 3A, 3B, and 3C.

In the first embodiment, the ESD protection circuit 21e is connected to the input pad 21a to which the input buffer 21c is connected, and the ESD protection circuit 22e is not connected to the input pad 22a to which the input buffer 22c is connected.

By contrast, in the second embodiment, input buffers 21c and 22c and ESD protection circuits 21e and 22e are connected to different input pads, and the ESD protection circuits 21e and 22e can selectively be connected by wire bonding.

That is, as shown in FIG. 3B, an input pad 21a-1 is formed adjacent to an input pad 21a in a first semiconductor chip 21. The ESD protection circuit 21e is connected to the input pad 21a-1 by an interconnection 21g. The interconnection 21g is, e.g., the lowermost metal interconnection extracted from the input pad 21a, and desirably has a low resistance.

On the other hand, as shown in FIG. 3C, an input pad 22a-1 is formed adjacent to an input pad 22a in each of a plurality of second semiconductor chips 22. The ESD protection circuit 22e is connected to the input pad 22a-1 by an interconnection 22g. The interconnection 22g is, e.g., the lowermost metal interconnection extracted from the input pad 22a, and desirably has a low resistance.

In the above arrangement as shown in FIGS. 3A, 3B, and 3C, an input pad 30 to which an input pin is connected, the input pad 21a, and the plurality of input pads 22a are bonded by a bonding wire, and the input pad 30 and the input pad 21a-1 of the first semiconductor chip 21 are bonded by a bonding wire. That is, a bonding wire 29 is first bonded to the input pad 30, then bonded to the input pad 21a of the first semiconductor chip 21, and finally bonded to the input pads 22a of second semiconductor chips 22 to 28. Thus, the input pad 30, the input pad 21a, and the plurality of input pads 22a are electrically connected.

In addition, the input pad 30 and the input pad 21a of the first semiconductor chip 21 are connected by a bonding wire 29-1. Alternatively, the input pad 30, input pad 21a, input pad 21a-1, and input pad 22a can be bonded in this order by the bonding wire 29 instead of the bonding wire 29-1, or the input pad 30, input pad 21a-1, input pad 21a, and input pad 22a can be bonded in this order by the bonding wire 29.

Also, in each of the second semiconductor chips 22 to 28, the input pad 22a-1 is not connected to any bonding wire but held open. Accordingly, only the ESD protection circuit 21e of the first semiconductor chip 21 is electrically connected to the input pad 30.

### (Effects)

In the second embodiment described above, the ESD protection circuits 21e and 22e and the input pads 21a-1 and 22a-1 connected to the ESD protection circuits 21e and 22e are formed in the first semiconductor chip 21 and the plurality of second semiconductor chips 22 to 28, only the input pad 21a-1 of the first semiconductor chip 21 is connected to the input pad 30 to which the input pin is connected by the bonding wire 29-1, and the input pads 22a-1 of the plurality of semiconductor chips 22 to 28 are not connected to any bonding wire but kept open. Therefore, only the ESD protection circuit 21e of the first semiconductor chip 21 is connected to the input pad 30. This makes it possible to reduce the capacitance connected to the input pad 30, and prevent a decrease in signal propagation speed.

Also, the first and second semiconductor chips 21 and 22 have the same arrangement except for a bonding step for the input pad 21a-1 or 22a-1 connected to the ESD protection circuit 21e or 22e. This facilitates manufacture because the first and second semiconductor chips 21 and 22 can be manufactured by the same process.

Furthermore, the ESD protection circuit 21e closest to the input pad 30 to which the input pin is connected is set in a functional state. That is, the ESD protection circuit 21e of the first semiconductor chip 21 positioned close to the input pad is set in a functional state. On the other hand, the ESD protection circuit 22e of the second semiconductor chip 22 beyond the ESD protection circuit 21e of the first semiconductor chip 21 is set in an unfunctional state. That is, the first semiconductor chip 21 to which ESD is most strongly applied is strongly protected against ESD, and the second semiconductor chip 22 to which ESD is not strongly applied is weakly protected against ESD. Consequently, it is possible to provide a semiconductor device having sufficient protection against ESD, and capable of a high-speed operation by preventing a decrease in signal propagation speed caused by the protection circuit.

### Third Embodiment

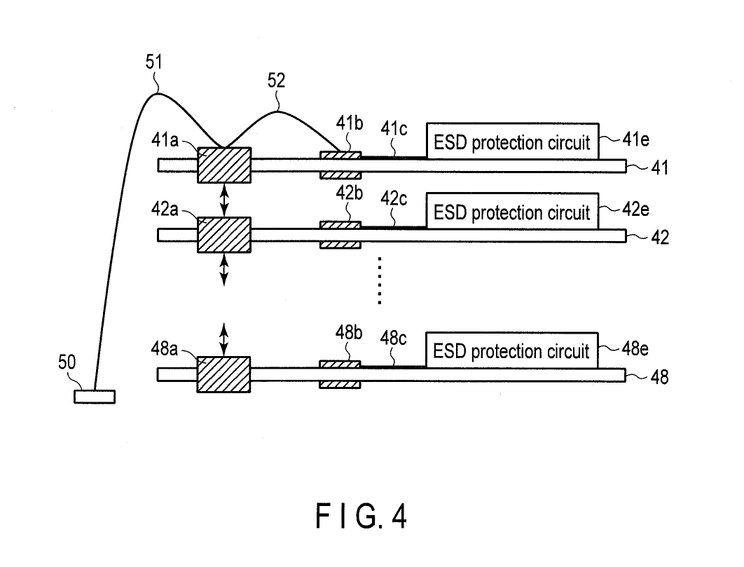

FIG. 4 shows the third embodiment.

In the first and second embodiments, the first semiconductor chip 21 and the plurality of second semiconductor chips 22 are stacked as they are shifted from each other at a predetermined interval, and their input pads are connected by the bonding wire 29.

By contrast, in the third embodiment, through silicon vias (TSVs) 41a to 48a are formed in a first semiconductor chip 41 and a plurality of second semiconductor chips 42 to 48, and the first semiconductor chip 41 and the plurality of second semiconductor chips 42 to 48 are stacked by electrically connecting the TSVs 41a to 48a by bringing them into contact with each other. The TSVs 41a to 48a are connected to internal circuits (not shown) formed in the first semiconductor chip 41 and second semiconductor chips 42 to 48. Note that the first semiconductor chip 41 is stacked in the uppermost layer.

In addition, the first semiconductor chip 41 and the plurality of second semiconductor chips 42 to 48 include input pads 41b and 42b to 48b, ESD protection circuits 41e and 42e to 48e, and interconnections 41c and 42c to 48c for respectively connecting the input pads 41b and 42b to 48b and ESD protection circuits 41e and 42e to 48e.

In the above-mentioned arrangement, the plurality of second semiconductor chips 48 to 42 are sequentially stacked via the TSVs 48a to 41a. In this state, the TSV 41a of the first semiconductor chip 41 and an input pad 50 to which an input pin is connected are connected by a bonding wire 51. Also, the TSV 41a and input pad 41b are connected by a bonding wire 52. Furthermore, the TSVs 42a to 48a and input pads 42b to 48b are not connected by any bonding wire but kept open. Accordingly, only the ESD protection circuit 41e formed in the first semiconductor chip 41 is electrically connected to the input pad 50, and the ESD protection circuits 42e to 48e do not function.

### (Effects)

In the third embodiment described above, in the first semiconductor chip 41 and second semiconductor chips 42 to 48 connected via the TSVs 41a to 48a, only the ESD protection circuit 41e of the first semiconductor chip 41 is connected to the input pad 50, and the ESD protection circuits 42e to 48e of the second semiconductor chips 42 to 48 are not connected to the input pad 50. This makes it possible to reduce the capacitance connected to the input pad 50, and prevent a decrease in signal propagation speed.

In addition, the first semiconductor chip 41 and the plurality of the second semiconductor chips 42 to 48 have the same arrangement, and hence can be manufactured by the same manufacturing steps. This can facilitate the manufacture.

Also, the ESD protection circuit 41e closest to the input pad 50 to which the input pin is connected is set in a functional state. That is, the ESD protection circuit 41e of the first semiconductor chip 41 positioned close to the input pin is set in a functional state. On the other hand, the ESD protection circuit 42e of the second semiconductor chip 42 beyond the ESD protection circuit 41e of the first semiconductor chip 41 is set in an unfunctional state. More specifically, the first semiconductor chip 41 to which ESD is most strongly applied is strongly protected against ESD, and the second semiconductor chip 42 to which ESD is not strongly applied is weakly protected against ESD. Consequently, it is possible to provide a semiconductor device having sufficient protection against ESD, and capable of a high-speed operation by preventing a decrease in signal propagation speed caused by the protection circuit.

### Fourth Embodiment

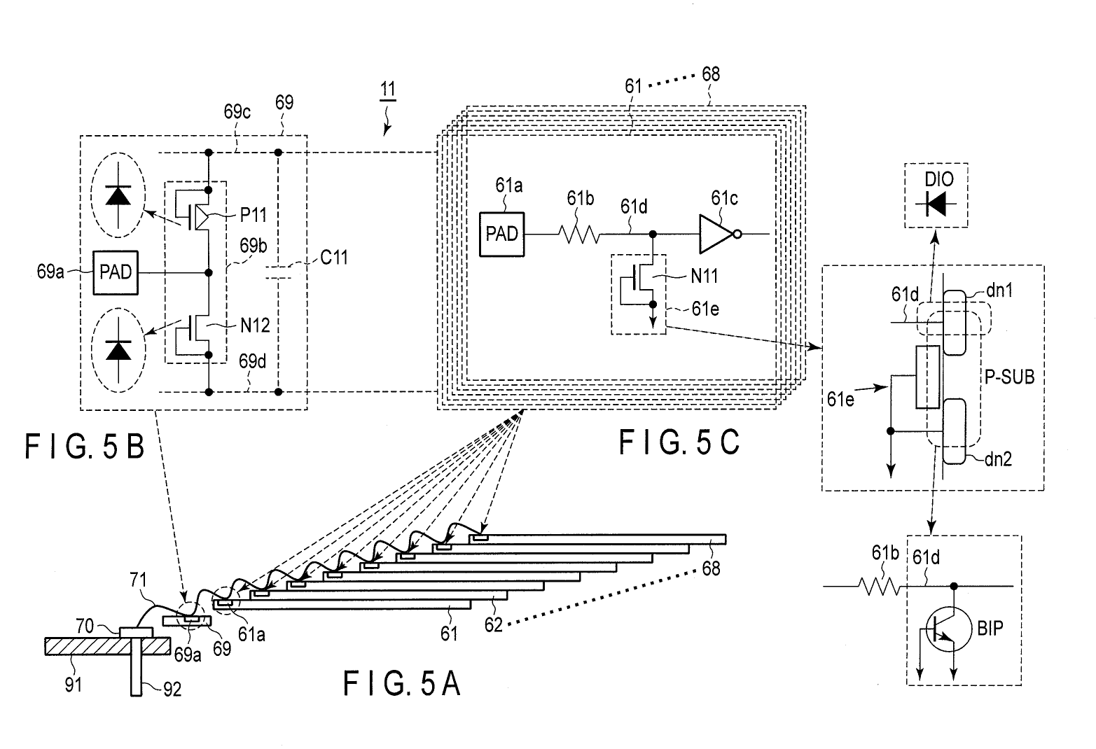

FIGS. 5A, 5B, and 5C show the fourth embodiment.

In the above-mentioned first to third embodiments, the ESD protection circuit having sufficient protection characteristics is formed in each semiconductor chip in order to protect a semiconductor device from static electricity discharged from a human body or the like.

By contrast, in the fourth embodiment, an ESD protection circuit 61e having a relatively low protection performance is formed in each of semiconductor chips 61 to 68 each incorporating, e.g., a NAND flash memory, and an ESD protection circuit 69b having a sufficient protection performance is formed in a semiconductor chip 69 different from the semiconductor chips 61 to 68 and dedicated for ESD protection. Also, the semiconductor chips 61 to 68 and semiconductor chip 69 are arranged on a base 91 having an input pad 70. The input pad 70 is connected to a pin 92.

The purpose of the ESD protection circuits 61e formed in the semiconductor chips 61 to 68 is to protect the semiconductor chips 61 to 68 against ESD during the manufacture and assembly, and have protection performance weaker than that of the ESD protection circuit 69b. On the other hand, the protection element parasitic capacitance of the ESD protection circuits 61e is set smaller than that of the ESD protection circuit 69b.

Referring to FIGS. 5A and 5C, the semiconductor chips 61 to 68 each include an input pad 61a, a protection resistance 61b, an input buffer 61c, and the ESD protection circuit 61e. The input pad 61a is connected to the input terminal of the input buffer 61c via the protection resistance 61b. The output terminal of the input buffer 61c is connected to an internal circuit (not shown). The protection resistance 61b is, e.g., the wiring resistance of a metal interconnection 61d extracted from the input pad 61a and formed in the lowermost layer, and has a resistance value of, e.g., about 300 Ω.

Also, the drain of, e.g., an NMOS transistor N11 forming the ESD protection circuit 61e is connected between the interconnection 61d and, e.g., ground. The gate electrode and source of the transistor N11 are grounded. The transistor N11 includes a diode DIO and a bipolar transistor BIP. For example, the diode DIO is formed by an n-type diffusion layer dn1 and a p-type substrate. The diode DIO is connected in the opposite direction between the interconnection 61d and ground. For example, the bipolar transistor BIP is formed by the n-type diffusion layer dn1, an n-type diffusion layer dn2, and the p-type substrate. A resistance 61b is connected to an emitter of the bipolar transistor BIP via the interconnection 61d. On the other word, the transistor N11 has a parasitic capacitance which is configured by the n-type diffusion layer dn1, the p-type substrate, and the n-type diffusion layer dn2. The gate width of the transistor N11 is set to be, e.g., approximately 1/20 or less the gate width of transistor N12 forming the ESD protection circuit 69d formed in a chip (to be described later) dedicated for an ESD protection circuit. That is, the transistor N11 is a protection element having a protecting function weaker than that of the transistor N12 forming the ESD protection circuit 69d. Also, the transistor N11 is a protection element having a parasitic capacitance smaller than that of the transistor N12 forming the ESD protection circuit 69d.

On the other hand, the semiconductor chip 69 dedicated for an ESD protection circuit shown in FIGS. 5A and 5B includes an input pad 69a, the ESD protection circuit 69b, and a capacitor C11. The semiconductor chip 69 dedicated for an ESD protection circuit has a power pad and ground pad (neither is shown), and these power pad and ground pad are electrically connected to power pads and ground pads (none of them is shown) of the semiconductor chips 61 to 68 by bonding wires. Note that a power line 69c is connected to the power pad, and a ground line 69d is connected to the ground pad.

The ESD protection circuit 69b includes the diode-connected PMOS transistor P11 and diode-connected NMOS transistor N12. The transistor P11 functions as a diode connected in the opposite direction between the power line 69c and input pad 69a. The transistor N12 functions as a diode connected in the opposite direction between the input pad 69a and ground line 69d. To obtain a sufficient ESD protecting function when the semiconductor device 11 is completed, the gate width of each of the transistors P11 and N12 is set to be ⅕ to 1/20 or more the gate width of the transistor N11 forming the ESD protection circuit 61e formed in each of the semiconductor chips 61 to 68.

Furthermore, the capacitor C11 is connected between the power line 69c and ground line 69d. The semiconductor chip 69 dedicated for an ESD protection circuit can also include a thyristor element or inverter element for supplying an electric current between the power supply and ground when a high voltage is applied to the input pad 69a.

As shown in FIG. 5A, the plurality of semiconductor chips 61 to 68 having the above arrangement are stacked as they are shifted from each other at a predetermined interval, thereby exposing the input pads 61a of these chips. A bonding wire 71 is continuously sequentially bonded to the exposed input pads 61a. That is, the bonding wire 71 is first bonded to the input pad 70 to which the input pin is connected, then bonded to the input pad 69a of the semiconductor chip 69 dedicated for an ESD protection circuit, and finally bonded to the input pads 61a of the semiconductor chips 61 to 68. Thus, the input pad 70, the input pad 69a, and the plurality of input pads 61a are electrically connected.

In this state in which the input pad 69a of the semiconductor chip 69 dedicated for an ESD protection circuit and the plurality of input pads 61a of the semiconductor chips 61 to 68 are connected by the bonding wire 71, only the ESD protection circuit 69b of the semiconductor chip 69 dedicated for ESD protection is practically connected to the bonding wire 71 and input pad 70.

That is, the capacitance of the ESD protection circuit 61e formed in each of the semiconductor chips 61 to 68 is much smaller than that of the ESD protection circuit 69b. Accordingly, only the ESD protection circuit 69b of the semiconductor chip 69 dedicated for ESD protection is practically connected to the bonding wire 71 and input pad 70.

### (Effects)

In the fourth embodiment described above, the semiconductor chips 61 to 68 each have the ESD protection circuit 61e, so the semiconductor chips 61 to 68 can be protected from electrostatic discharge when they are manufactured.

In addition, in the state in which the bonding wire 71 is connected to the input pad 69a of the semiconductor chip 69 dedicated for an ESD protection circuit and the plurality of input pads 61a of the semiconductor chips 61 to 68, only the ESD protection circuit 69b of the semiconductor chip 69 dedicated for an ESD protection circuit is practically connected to the bonding wire 71 and input pad 70. That is, the capacitance of the ESD protection circuit 61e formed in each of the semiconductor chips 61 to 68 is much smaller than that of the ESD protection circuit 69b. This makes it possible to reduce the capacitance connected to the bonding wire 71 and input pad 70, and prevent a decrease in signal propagation speed.

Also, the semiconductor chips 61 to 68 have the same arrangement. This facilitates the manufacture, and can suppress an increase in manufacturing cost.

Furthermore, the input pad 70 to which the input pin 92 is connected, the semiconductor chip 69, the first semiconductor element 61, and the second semiconductor element 62 are connected in this order by wire bonding. That is, the semiconductor chip 69 is positioned close to the input pin 92, so the ESD protection circuit 69d is set in a functional state. On the other hand, the protection circuits 61e having a weak protecting function are set in a functional state in the first and second semiconductor chips 61 and 62 beyond the ESD protection circuit 69d of the semiconductor chip 69. That is, the semiconductor chip 69 to which ESD is most strongly applied is strongly protected against ESD, and the first and second semiconductor chips 61 and 62 to which ESD is not strongly applied are weakly protected against ESD. Consequently, it is possible to provide a semiconductor device having sufficient protection against ESD, and capable of a high-speed operation by preventing a decrease in signal propagation speed caused by the protection circuit.

### Fifth Embodiment

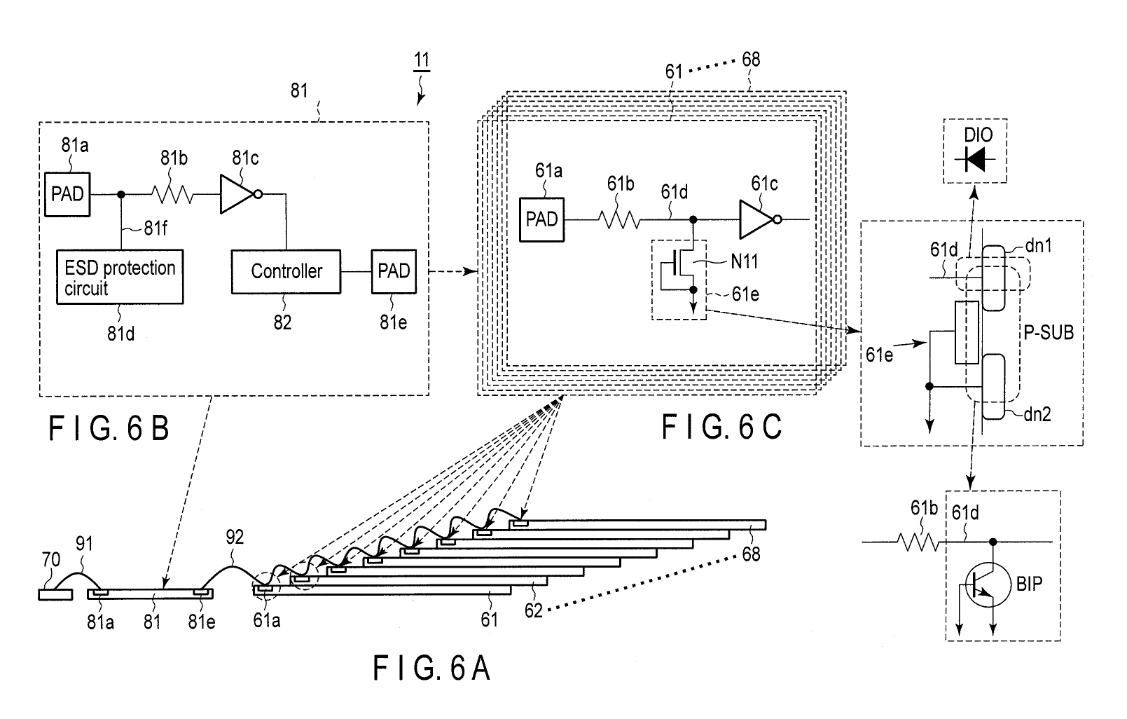

FIGS. 6A, 6B, and 6C show an outline of the fifth embodiment. The same reference numerals as in the fourth embodiment denote the same parts in FIGS. 6A, 6B, and 6C.

In the fourth embodiment, the semiconductor chip 69 dedicated for an ESD protection circuit is formed in addition to the plurality of semiconductor chips 61 to 68. By contrast, in the fifth embodiment, an ESD protection circuit is formed in a controller chip 81 formed independently of a plurality of semiconductor chips 61 to 68.

That is, as shown in FIGS. 6A and 6B, the controller chip 81 is formed near the plurality of semiconductor chips 61 to 68. The controller chip 81 can also be stacked together with the plurality of semiconductor chips 61 to 68. The semiconductor chips 61 to 68 and controller chip 81 are arranged on a base (not shown) having an input pad 70 to which an input pin is connected.

An ESD protection circuit 61e having a weak ESD protection performance is formed in each of the semiconductor chips 61 to 68.

The controller chip 81 includes a controller 82 for controlling the plurality of semiconductor chips 61 to 68, an input pad 81a, a protection resistance 81b, an input buffer 81c, an ESD protection circuit 81d, and an output pad 81e.

The input pad 81a is connected to the controller 82 via the protection resistance 81b and input buffer 81c. The output pad 81e is connected to the controller 82. The ESD protection circuit 81d is connected to the pad 81a via an interconnection 81f. The ESD protection circuit 81d is formed by, e.g., two diodes as shown in FIGS. 2A and 2B. The interconnection 81f is formed by, e.g., the lowermost metal interconnection extracted from the input pad 81a.

In the above arrangement, as shown in FIG. 6A, the input pad 81a is connected to the input pad 70 by a bonding wire 91. The output pad 81e is connected to the input pads 61a of the plurality of semiconductor chips 61 to 68 in order by a bonding wire 92. That is, the input pin is connected to the semiconductor chips 61 to 68 via the controller chip 81 including the ESD protection circuit 81d.

In the fifth embodiment described above, the semiconductor chips 61 to 68 each include the ESD protection circuit 61e. Accordingly, the semiconductor chips 61 to 68 can be protected from electrostatic discharge when they are manufactured.

Also, the controller chip 81 includes the ESD protection circuit 81d, and only the ESD protection circuit 81d of the controller chip 81 is connected, via the pad 81a and bonding wire 91, to the input pad 70 to which the input pin is connected. This makes it possible to reduce the capacitance of the input pad 70, and prevent a decrease in signal propagation speed.

In addition, the input pad 70 to which the input pin is connected is connected to the controller chip 81, first semiconductor element 61, and second semiconductor element 62 in this order. That is, the controller chip 81 is positioned close to the input pin, so the ESD protection circuit 81d is set in a functional state. On the other hand, the protection circuits 61e having a weak protecting function are set in a functional state in the semiconductor chips 61 to 68 beyond the ESD protection circuit 81d of the controller chip 81. That is, the controller chip 81 to which ESD is most strongly applied is strongly protected against ESD, and the semiconductor chips 61 to 68 to which ESD is not strongly applied are weakly protected against ESD. Consequently, it is possible to provide a semiconductor device having sufficient protection against ESD, and capable of a high-speed operation by preventing a decrease in signal propagation speed caused by the protection circuit.

Furthermore, the input pin is connected to the semiconductor chips 61 to 68 via the controller chip 81. This increases the efficiency at which the controller chip 81 controls the semiconductor chips 61 to 68, and makes a high-speed operation of the semiconductor device feasible. Also, no chip dedicated for an ESD protection circuit needs be formed because the controller chip 81 includes the ESD protection circuit 81d. As a result, the semiconductor device can be down-sized.

Note that the TSVs described in the third embodiment are also applicable to the fourth and fifth embodiments. In this case, it is possible to form an ESD protection circuit in an interface chip for controlling each semiconductor chip, and use this ESD protection circuit of the interface chip. By electrically connecting the input pin to each semiconductor chips via the interface chip, it is possible to provide a semiconductor device having sufficient protection against ESD, and capable of a high-speed operation by preventing a decrease in signal propagation speed caused by the protection circuit.

### Sixth Embodiment

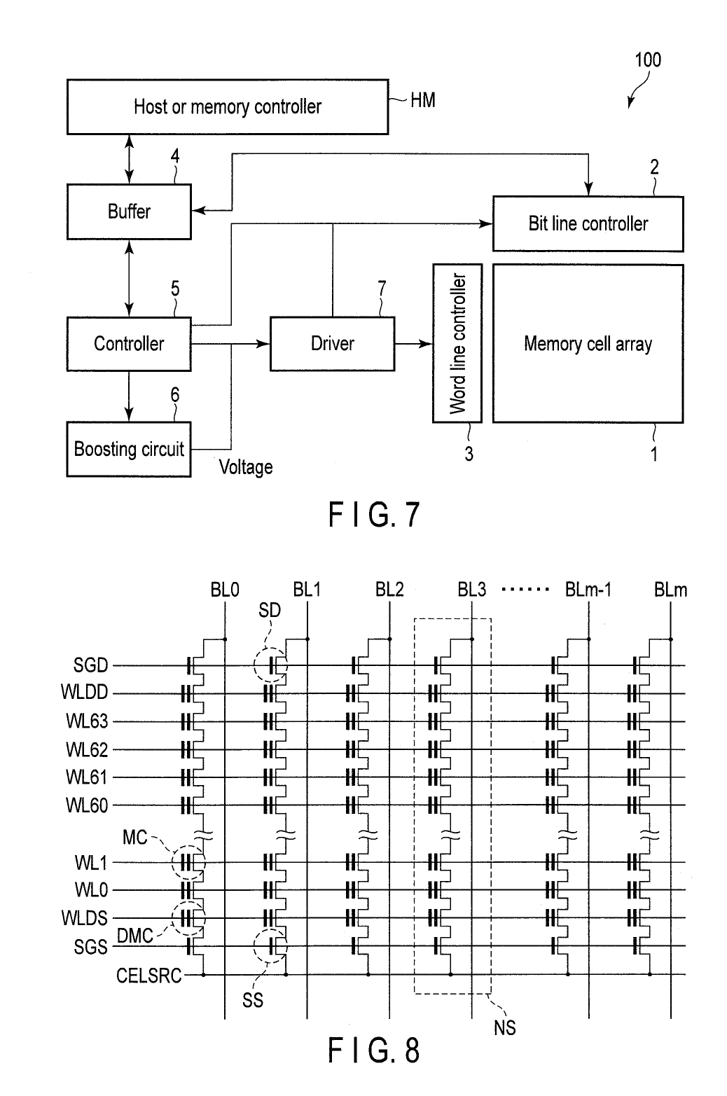

FIGS. 7 and 8 show a NAND flash memory as an example of a semiconductor device applicable to the sixth embodiment. The arrangement of the NAND flash memory will be explained below with reference to FIGS. 7 and 8.

FIG. 7 is a block diagram showing an example of the arrangement of the NAND flash memory. A NAND flash memory 100 includes a memory cell array 1 in which memory cells MC for storing data area arranged in a matrix. The memory cell array 1 includes a plurality of bit lines BL, a plurality of word lines WL, a source line SRC, and a plurality of memory cells MC shown in FIG. 8. Each memory cell MC can store n-bit (n is a natural number of 1 or more) data.

A host or memory controller HM outputs various commands CMD, an address ADD, and data DT for controlling the operation of the NAND flash memory. The commands CMD, address ADD, and data DT are input to a buffer 4. Write data input to the buffer 4 is supplied to a bit line BL_{S} selected by a bit line controller 2. The various commands CMD and address ADD are input to a controller 5, and the controller 5 controls a boosting circuit 6 and driver 7 based on the commands CMD and address ADD. Control signals ALE (Address Latch Enable), CLE (Command Latch Enable), WE (Write Enable), and RE (Read Enable) are also input to the buffer 4. The controller 5 can also control an output buffer circuit and the like formed in the buffer 4.

The boosting circuit 6 generates voltages necessary for write, read, and erase, and applies the generated voltages to the driver 7, under the control of the controller 5. The driver 7 applies these voltages to the bit line controller 2 and a word line controller 3 under the control of the controller 5. Based on these voltages, the bit line controller 2 and word line controller 3 read out data from the memory cell MC, write data in the memory cell MC, and erase data from the memory cell MC.

The memory cell array 1 is connected to the bit line controller 2 for controlling the voltage of the bit line BL, and the word line controller 3 for controlling the voltage of the word line WL. The bit line controller 2 and word line controller 3 are connected to the driver 7.

The driver 7 controls the bit line controller 2 based on the address ADD, and reads out data from the memory cell MC in the memory cell array 1 via the bit line BL. Also, the driver 7 controls the bit line controller 2 based on the address ADD, and writs data in the memory cell MC of the memory cell array 1 via the bit line BL.

The bit line controller 2, word line controller 3, driver 7, and controller 5 will generally be referred to as “a controller” in some cases.

FIG. 8 shows an example of the circuit configuration of the memory cell array 1 shown in FIG. 7. A plurality of memory cells are arranged in the memory cell array 1. One NAND string NS includes a memory string including, e.g., 64 memory cells MC connected in series in the bit line direction, and selection transistors SD and SS. Note that a dummy memory cell DMC may also be formed between the memory string and selection transistor SD, and between the memory string and selection transistor SS.

A plurality of NAND strings NS are arranged in the word line direction (m+1 strings in the example shown in FIG. 8). One of a plurality of bit lines BL is connected to one end of the NAND string NS, and a common source line CELSRC is connected to the other end. The selection transistors SD and SS are respectively connected to selection gate lines SGD and SGS. The unit of the plurality of NAND strings NS arranged in the word line direction will be referred to as a block hereinafter.

The word line WL runs in the word line direction, and connects the memory cells MC arranged in the word line direction together. The memory cells MC connected in the word line direction form one page. Write to the memory cells MC is performed page by page.

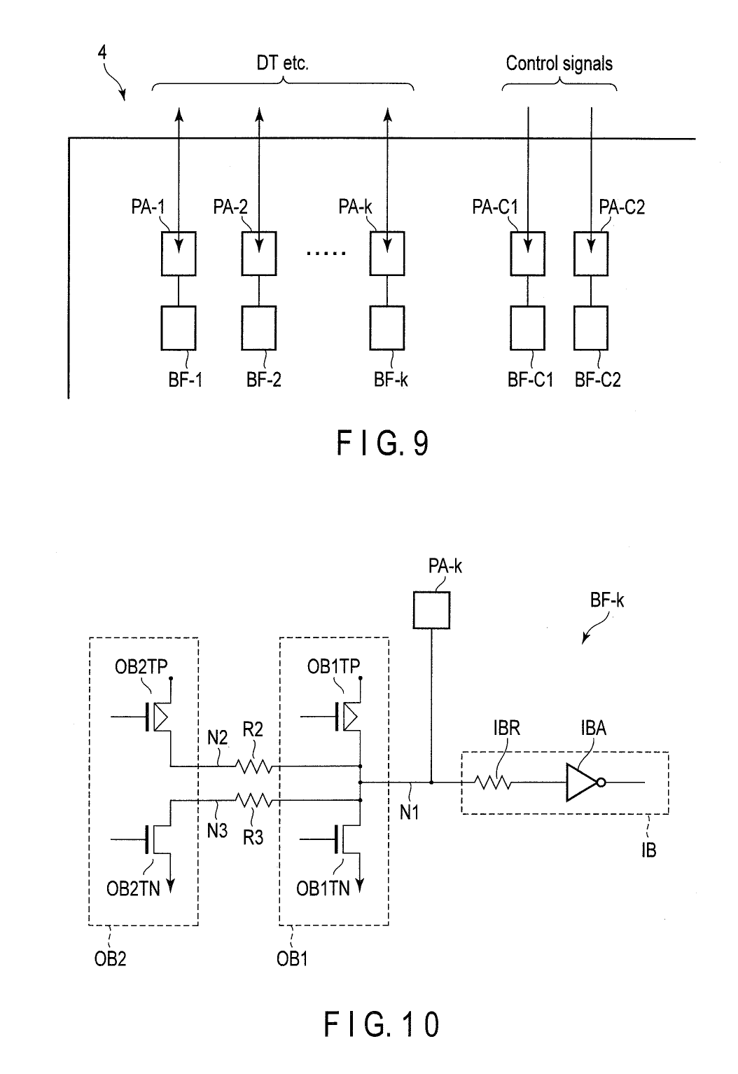

FIG. 9 is a block diagram showing an example of the buffer 4 formed in the NAND flash memory.

A plurality of pads PA are arranged in the buffer 4. Bonding wires, through hole vias, and the like are connected to the pads PA. Signals such as the data DT are input from the host or memory controller HM to the pads PA via the bonding wires, through hole vias, and the like. Assume that pads to which the data DT, command CMD, address ADD, and the like are input are pads PA-1 to PA-k (k is an integer of 1 or more), and pads to which control signals such as a write enable signal and chip enable signal are input are pads PA-C1 and PA-C2. Note that two or more pads PA-C1 and two or more pads PA-C2 may also be formed.

Buffer units BF-1 to BF-k are respectively connected to the pads PA-1 to PA-k. Buffer units BF-C1 and BF-C2 are respectively connected to the pads PA-C1 and PA-C2.

Note that the NAND flash memory 100 also includes pads to which a ground voltage VSS and external voltage VEXT are applied. To form a current path for escaping a surge voltage, a protection element can be connected to the pad to which the external voltage is applied.

FIG. 10 is a circuit diagram showing an example of the buffer unit BF-k. Note that the buffer unit BF-k will be explained as an example of the buffer units BF-1 to BF-k. The remaining buffer units BF-1 to BF-(k−1) can also have the same arrangement. The buffer unit BF-k is connected to the pad PA-k via a node N1.

The buffer unit BF-k includes an input buffer unit IB and two kinds of output buffer circuits OB1 and OB2. The input buffer unit IB and output buffer circuit OB1 are connected to the node N1. The output buffer circuit OB2 is also connected to the node N1, and connected to the output buffer circuit OB1 via the node N1.

The input buffer unit IB includes a protection resistance IBR and input buffer IBA. The input buffer IBA is connected to the node N1 via the protection resistance IBR. The protection resistance IBR is, e.g., the wiring resistance of a metal interconnection formed in the lowermost layer of a plurality of metal interconnection layers (not shown) arranged in the NAND flash memory, and has a resistance value of, e.g., about 300 Ω.

The output buffer circuit OB1 includes one PMOS transistor OB1TP and one NMOS transistor OB1TN. The PNOS transistor OB1TP has one terminal connected to the node N1, and the other terminal connected to the power supply voltage VEXT. The NMOS transistor OB1TN has one terminal connected to the node N1, and the other terminal connected to the ground voltage VSS. The controller 5 can switch the ON and OFF states of the PMOS transistor OB1TP and NMOS transistor OB1TN by controlling the gate electrodes (control lines) of the PMOS transistor OB1TP and NMOS transistor OB1TN.

The output buffer circuit OB2 includes one PMOS transistor OB2TP and one NMOS transistor OB2TN. The PMOS transistor OB2TP has one terminal connected to a node N2, and the other terminal connected to the power supply voltage VEXT. The NMOS transistor OB2TN has one terminal connected to a node N3, and the other terminal connected to the ground voltage VSS. The node N2 is connected to the node N1 via a resistance R2. The node N3 is connected to the node N1 via a resistance R3.

The resistances R2 and R3 are, e.g., the wiring resistances of the lowermost layer. Note that a metal interconnection, polysilicon, or the like can be used as an interconnection. The NAND flash memory includes a plurality of interconnection layers for connecting circuit elements. Of the interconnection layers, the lowermost interconnection layer has the highest resistance value in many cases. Therefore, the node N1 is connected to the nodes N2 and N3 via the lowermost interconnection layer. For example, the node N1 is the uppermost interconnection layer, and connected to the lowermost interconnection layer via a contact or the like. This lowermost interconnection layer is extended by a predetermined distance, and connected to a contact CT2 of the PMOS transistor OB2TP (to be described later) and a contact CT2 of the NMOS transistor OB2TN as the node 3.

Note that each of the resistances R2 and R3 can also be a resistance element using a gate electrode or a resistance element including an element region.

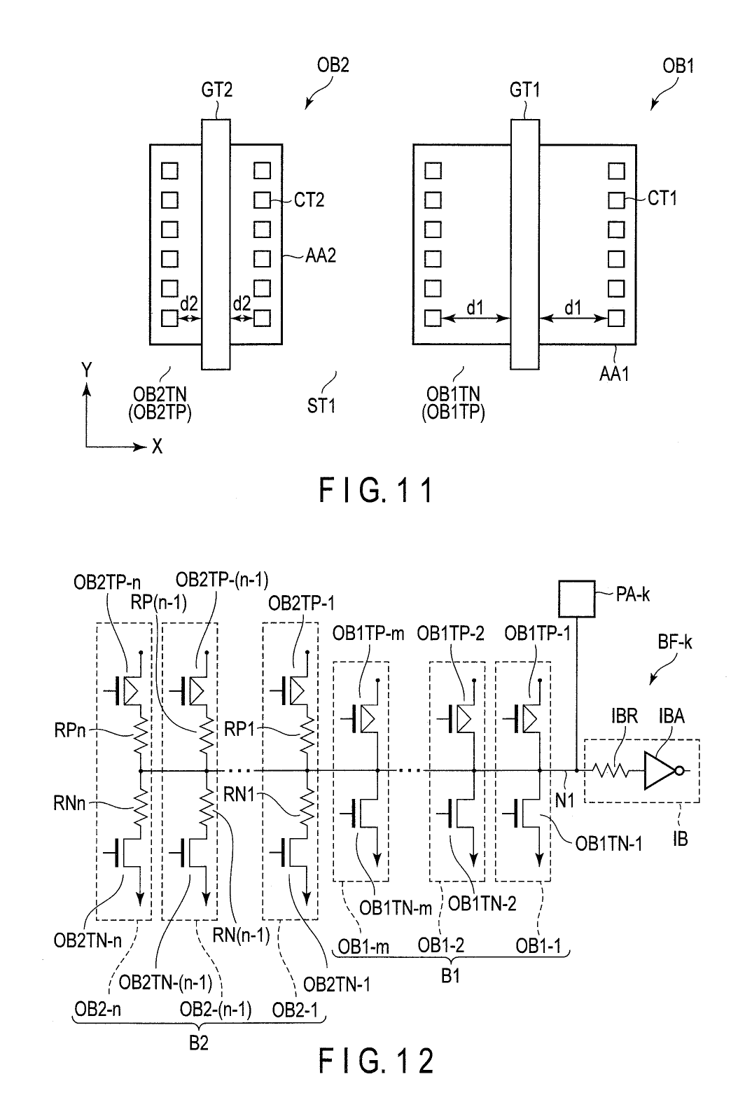

FIG. 11 shows examples of the layouts of the NMOS transistors OB1TN and OB2TN arranged in the output buffer circuits OB1 and OB2. Note that FIG. 11 shows the NMOS transistors as examples, but the same arrangements are also applicable to the PMOS transistors OB1TP and OB2TP.

The NMOS transistor OB1TN includes an element region AA1 isolated by an element isolation insulating film ST1, a gate electrode GT1, and contacts CT1. The gate electrode GT1 extends in the Y direction and divides the element region AA1 in the X direction. Diffusion layers are formed in the element regions AA1 divided in the X direction, and function as source and drain regions. A plurality of contacts CT1 are arranged in each of the source and drain regions. The contacts CT1 are arranged in a line in the Y direction. The distance between the gate electrode GT1 and each contact CT1 is a distance d1.

The NMOS transistor OB2TN includes an element region AA2 isolated by an element isolation insulating film ST1, a gate electrode GT2, and contacts CT2. The gate electrode GT2 extends in the Y direction and divides the element region AA2 in the X direction. Diffusion layers are formed in the element regions AA2 divided in the X direction, and function as source and drain regions. A plurality of contacts CT2 are arranged in each of the source and drain regions. The contacts CT2 are arranged in a line in the Y direction. The distance between the gate electrode GT2 and each contact CT2 is a distance d2.

The distance d1 is larger than the distance d2. That is, when the diffusion layer capacitances per unit area of the NMOS transistors OB1TN and OB2TN are almost the same, the diffusion layer capacitance of the NMOS transistor OB1TN is larger than that of the NMOS transistor OB2TN. Consequently, the function as a protection element of the NMOS transistor OB1TN is higher than that of the NMOS transistor OB2TN.

The PMOS transistors OB1TP and OB2TP also have the same relationship. That is, when the diffusion layer capacitances per unit area of the PMOS transistors OB1TP and OB2TP are almost the same, the diffusion layer capacitance of the PMOS transistor OB1TP is larger than that of the PMOS transistor OB2TP. Consequently, the function as a protection element of the PMOS transistor OB1TP is higher than that of the NMOS transistor OB2TP.

That is, the output buffer circuit OB1 has not only the function of an output buffer but also the function of a protection element.

Note that the widths of the gate electrodes GT1 and GT2 can be the same or different.

### (Effects)

The surge breakdown voltage of a semiconductor device can be increased by connecting the output buffer circuit OB1 to the node N1 connected to the pad PA-k. On the other hand, the output buffer circuit OB2 is connected to the output buffer circuit OB1 via the resistances R2 and R3. That is, when a surge voltage enters the pad PA-1k, the resistances R2 and R3 increase the time constants of the nodes N2 and N3. Consequently, the surge voltage goes to the power supply voltage or ground voltage through the output buffer circuit OB1 before a large electrical stress is applied to the NMOS transistor OB2TN and PMOS transistor OB2TP. As a result, no large electrical stress is applied to the NMOS transistor OB2TN and PMOS transistor OB2TP. Accordingly, the NMOS transistor OB2TN and PMOS transistor OB2TP can be downsized. Note that it is also possible to form only one of the resistances R2 and R3.

If the output buffer circuit OB2 is replaced with the output buffer circuit OB1 in order to satisfy the product standards, the operation of the semiconductor device slows down. That is, since the output buffer circuit OB1 having a larger diffusion layer capacitance is used as all the output buffers, the pin capacitance increases, and the operation of the semiconductor device slows down.

Accordingly, the diffusion layer capacitance of the output buffer circuit OB1 positioned close to the pad PA-k is increased, thereby increasing the function as a protection element. On the other hand, the pin capacitance can be decreased by decreasing the diffusion layer capacitance of the output buffer circuit OB2 connected to the pad PA-k via the resistances R2 and R3. As a consequence, a semiconductor device capable of a high-speed operation can be provided without weakening protection against ESD.

Also, the adjustment of the diffusion layer capacitance is not limited to changing the distance between the gate electrode and contact. For example, the diffusion layer capacitance can also be adjusted by changing the capacitance value by changing the impurity concentration in the diffusion layer.

Note that the sizes of the NMOS transistor and PMOS transistor are sometimes different. If this is the case, it is only necessary to satisfy the relationship “distance d1>distance d2” between the NMOS transistors OB1TN and OB2TN, and satisfy the relationship “distance d1>distance d2” between the PMOS transistors OB1TP and OB2TP.

### First Modification

FIG. 12 is a circuit diagram showing an example of the first modification of the buffer unit BF. Note that the same reference numerals as in the previous drawings denote the same parts in FIG. 12.

As shown in FIG. 12, a plurality of output buffer circuits OB1-1 to OB1-m (m is an integer of 2 or more) form an output buffer circuit group B1. The output buffer circuits OB1-1 to OB1-m are connected in series to a node N1. The output buffer circuits OB1-1 to OB1-m respectively include PMOS transistors OB1TP-1 to OB1TP-m and NMOS transistors OB1TN-1 to OB1TN-m.

The PMOS transistors OB1TP-1 to OB1TP-m each have one terminal connected to the node N1, and the other terminal connected to a power supply voltage VEXT. The NMOS transistors OB1TN-1 to OB1TN-m each have one terminal connected to the node N1, and the other terminal connected to a ground voltage VSS. A controller 5 can switch the ON and OFF states of the PMOS transistors OB1TP-1 to OB1TP-m and NMOS transistors OB1TN-1 to OB1TN-m by controlling the gate electrodes (control lines) of the PMOS transistors OB1TP-1 to OB1TP-m and NMOS transistors OB1TN-1 to OB1TN-m.

The PMOS transistors OB1TP-1 to OB1TP-m are connected in parallel to the node N1, and the NMOS transistors OB1TN-1 to OB1TN-m are connected in parallel to the node N1.

Also, a plurality of output buffer circuits OB2-1 to OB2-n (n is an integer of 2 or more) form an output buffer circuit group B2. The output buffer circuits OB2-1 to OB2-n are connected in series to the node N1. The output buffer circuits OB2-1 to OB2-n respectively include PMOS transistors OB2TP-1 to OB2TP-n and NMOS transistors OB2TN-1 to OB2TN-n.

One terminal of each of the PMOS transistors OB2TP-1 to OB2TP-n is connected to the power supply voltage VEXT. One terminal of each of the NMOS transistors OB2TN-1 to OB2TN-n is connected to the ground voltage VSS. The other-terminal sides of the PMOS transistors OB2TP-1 to OB2TP-n of the output buffer circuits OB2-1 to OB2-n are connected to the node N1 via resistances RP1 to RPn, respectively. The other-terminal sides of the NMOS transistors OB2TN-1 to OB2TN-n of the output buffer circuits OB2-1 to OB2-n are connected to the node N1 via resistances RN1 to RNn, respectively. The resistances RP1 to RPn and RN1 to RNn are, e.g., the wiring resistances of the lowermost layer. Each of the resistances RP1 to RPn and RN1 to RNn may also be the wiring resistance of an upper layer or a resistance element using a gate electrode.

The controller 5 can switch the ON and OFF states of the PMOS transistors OB2TP-1 to OB2TP-n and NMOS transistors OB2TN-1 to OB2TN-n by controlling the gate electrodes (control lines) of the PMOS transistors OB2TP-1 to OB2TP-n and NMOS transistors OB2TN-1 to OB2TN-n.

The PMOS transistors OB2TP-1 to OB2TP-n are connected in parallel to the node N1, and the NMOS transistors OB2TN-1 to OB2TN-n are connected in parallel to the node N1.

Also, the PMOS transistors OB1TP-1 to OB1TP-m and OB2TP-1 to OB2TP-n are connected in parallel to the node N1, and the NMOS transistors OB1TN-1 to OB1TN-m and OB2TN-1 to OB2TN-n are connected in parallel to the node N1.

Furthermore, the layout of each of the PMOS transistors OB1TP-1 to OB1TP-m and NMOS transistors OB1TN-1 to OB1TN-m arranged in the output buffer circuits OB1-1 to OB1-m is the same as that of the NMOS transistor OB1TN (OB1TP) shown in FIG. 11. Likewise, the layout of each of the PMOS transistors OB2TP-1 to OB2TP-n and NMOS transistors OB2TN-1 to OB2TN-n arranged in the output buffer circuits OB2-1 to OB2-n is the same as that of the NMOS transistor OB2TN (OB2TP) shown in FIG. 11.

### (Effects)

The first modification can achieve the same effects as those of the sixth embodiment.

Also, the user sometimes adjusts the output after the product is shipped. In this case, the host or memory controller HM causes the controller 5 to make some of the output buffer circuits OB2-1 to OB2-n inoperable. For example, to make the output buffer OB2-n inoperable, the host or memory controller HM causes the controller 5 to transmit, to the control lines of the NMOS transistor OB2TN-n and PMOS transistor OB2TP-n, a signal for turning off these transistors.

Also, the resistance is connected between the node N1 and one terminal of each of the PMOS transistors OB2TP-1 to OB2TP-n. That is, the resistances RP1 to RPn are connected between the node N1 and power supply voltage VEXT with respect to the output buffer circuits OB2-1 to OB2-n, respectively. Consequently, even when the distance d2 between the gate electrode GT2 and contacts CT2 of the PMOS transistors OB2TP-1 to OB2TP-n is shortened by the resistances RP1 to RPn, the surge breakdown voltage of the output buffer circuits OB2-1 to OB2-n can be maintained. This makes it possible to downsize the PMOS transistors OB2TP-1 to OB2TP-n.

Similarly, the resistance is connected between the node N1 and one terminal of each of the NMOS transistors OB2TN-1 to OB2TN-n. That is, the resistances RN1 to RNn are connected between the node N1 and power supply voltage VEXT with respect to the output buffer circuits OB2-1 to OB2-n, respectively. Consequently, even when the distance d2 between the gate electrode GT2 and contacts CT2 of the NMOS transistors OB2TN-1 to OB2TN-n is shortened by the resistances RN1 to RNn, the surge breakdown voltage of the output buffer circuits OB2-1 to OB2-n can be maintained. This makes it possible to downsize the NMOS transistors OB2TN-1 to OB2TN-n. It is also possible to arrange only the resistances RP1 to RPn or resistances RN1 to RNn.

Note that either of the integers m and n can be larger than the other when they have different values, and they can also have the same value.

### Second Modification

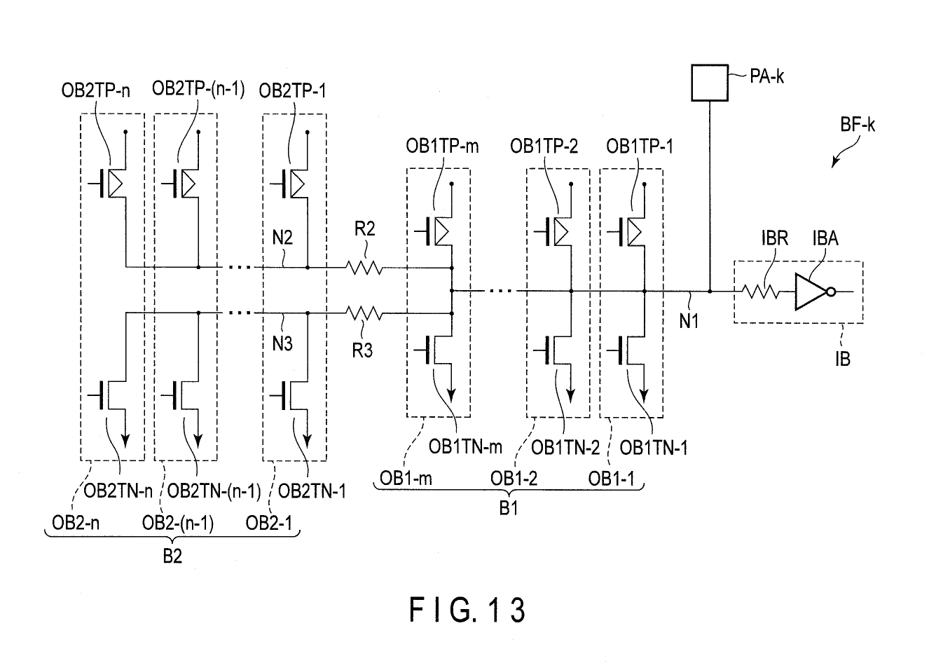

FIG. 13 is a circuit diagram showing an example of the second modification of the buffer unit BF. Note that the same reference numerals as in the previous drawings denote the same parts in FIG. 13.

Output buffer circuits OB2-1 to OB2-n of the second modification are connected in almost the same way as that of the output buffer circuit OB2 shown in FIG. 12. PMOS transistors OB2TP-1 to OB2TP-n each have one terminal connected to a power supply voltage VEXT, and the other terminal connected to a node N2. NMOS transistors OB2TN-1 to OB2TN-n each have one terminal connected to a ground voltage VSS, and the other terminal connected to a node N3. The node N2 is connected to a node N1 via a resistance R2. The node N3 is connected to the node N1 via a resistance R3.

For example, the PMOS transistors OB2TP-1 to OB2TP-n and NMOS transistors OB2TN-1 to OB2TN-n are connected to the nodes N2 and N3 by an upper interconnection layer having a low wiring resistance. On the other hand, the node N1 is connected to the nodes N2 and N3 by a lower interconnection layer having a high wiring resistance.

### (Effects)

The second modification can achieve the same effects as those of the sixth embodiment and first modification. In addition, the resistances R2 and R3 are arranged near the connections between the node N1 and the nodes N2 and N3. Consequently, it is possible to reduce the number of resistances and downsize the NAND flash memory 100.

Also, the NMOS transistor OB2TN and PMOS transistor OB2TP are often arranged apart from each other in order to increase the breakdown voltage. Therefore, the resistances R2 and R3 are collectively arranged near the node N1 and the nodes N2 and N3 as interconnection division points. This can make the interconnection layout easier than those of the sixth embodiment and first modification. Note that it is also possible to form only one of the resistances R2 and R3.

### Seventh Embodiment

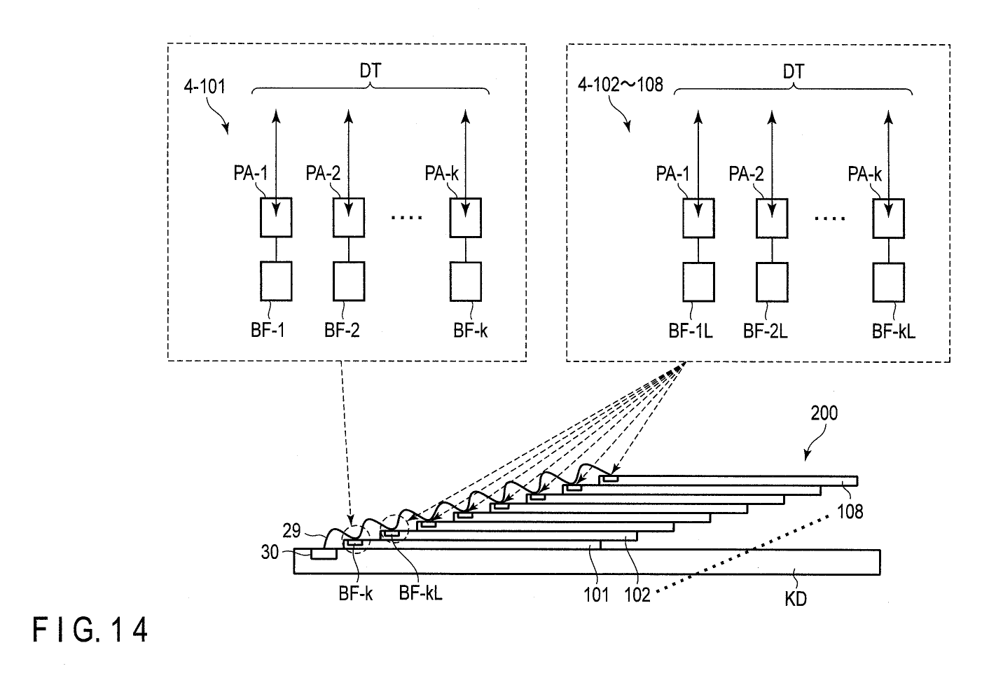

The seventh embodiment is directed to a semiconductor device in which a plurality of semiconductor chips are stacked. FIG. 14 shows an example of the semiconductor device according to the seventh embodiment.

In a semiconductor device 200 according to the seventh embodiment as shown in FIG. 14, a first semiconductor chip 101 placed on a base KD and a plurality of second semiconductor chips 102 to 108 are stacked as they are shifted from each other at a predetermined interval. The base KD has an input pin connection pad 30 to which an input pin is connected. The first semiconductor chip 101 and the plurality of second semiconductor chips 102 to 108 have the same size when viewed from above. Of the plurality of semiconductor chips, the first semiconductor chip 101 is placed in the lowermost layer. Note that the number of semiconductor chips of the semiconductor device 200 explained as an example is eight, but the number of first semiconductor chips and the number of second semiconductor chips need only be one.

For example, each of the first semiconductor chip 101 and the plurality of second semiconductor chips 102 to 108 is the NAND flash memory 100 explained in the sixth embodiment. Also, the first semiconductor chip 101 and the plurality of second semiconductor chips 102 to 108 have almost the same arrangement. However, the second semiconductor chips 102 to 108 each have buffer units BF1L to BFkL instead of buffer units BF1 to BFk of the first semiconductor chip 101.

The first semiconductor chip 101 is, e.g., a NAND flash memory including the buffer unit explained with reference to FIGS. 10 to 13.

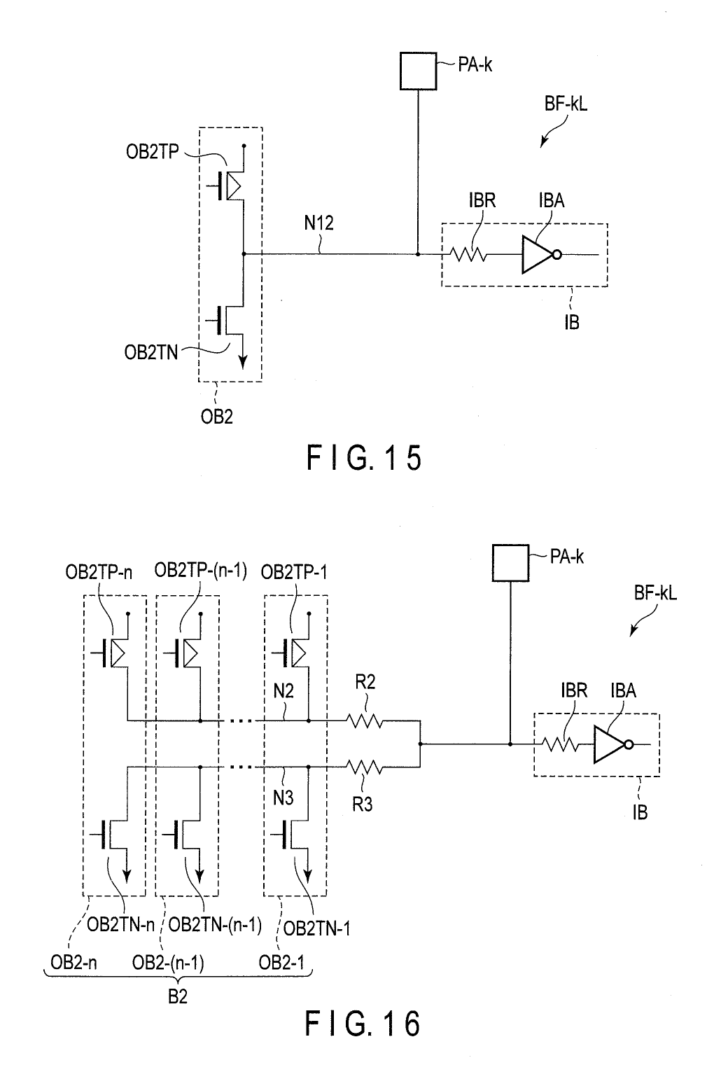

Each of the second semiconductor chips 102 to 108 is, e.g., a NAND flash memory including a buffer unit BF-kL shown in FIG. 15. FIG. 15 is a circuit diagram showing an example of the buffer unit BF-kL of the second semiconductor chips 102 to 108.

The buffer unit BF-kL will be explained as an example of the buffer units BF-1L to BF-kL. The remaining buffer units BF-1L to BF-(k−1)L can also have the same arrangement. The buffer unit BF-kL replaces the buffer units BF-1 to BF-k shown in FIG. 9.

The buffer unit BF-kL has no output buffer circuit OB1 when compared to the buffer unit BF-k. An output buffer unit OB2 is connected to a pad PA-k via a node N12.

The output buffer circuit OB2 includes a PMOS transistor OB2TP and NMOS transistor OB2TN. The POS transistor OB2TP has one terminal connected to the power supply voltage, and the other terminal connected to the node N12. The NMOS transistor OB2TN has one terminal connected to the node N12, and the other terminal connected to the ground voltage. The layout of the PMOS transistor OB2TP and NMOS transistor OB2TN is the same as that shown in FIG. 11, so a repetitive explanation will be omitted.

In the semiconductor device 200 shown in FIG. 14, a buffer 4-101 of the first semiconductor chip 101 has a high protection element function, but has a relatively large pin capacitance. On the other hand, buffers 4-102 to 4-108 of the second semiconductor chips 102 to 108 have a low protection element function, but have a small pin capacitance.

As shown in FIG. 14, the first semiconductor chip 101 and second semiconductor chips 102 to 108 having the above arrangement are stacked as they are shifted from each other at a predetermined interval, thereby exposing the pads PA of these chips. A bonding wire 29 is continuously sequentially bonded to the exposed pads PA.

That is, the bonding wire 29 is first bonded to the input pad 30 which is formed on the base KD and to which the input pin is connected. The input pad 30 connects the stacked first semiconductor chip 101 and second semiconductor chips 102 to 108 to an external circuit.

Then, the bonding wire 29 bonded to the input pad 30 is bonded to the pad PA of the first semiconductor chip 101, and bonded to the pads PA of the second semiconductor chips 102 to 108. Thus, the input pad 30, the pad PA of the first semiconductor chip 101, and the pads PA of the second semiconductor chips 102 to 108 are electrically connected.

Note that the pads PA connected by the bonding wire 29 in the first semiconductor chip 101 and second semiconductor chips 102 to 108 have the same function. For example, the pad PA-k of the first semiconductor chip to which data DT is input is connected to the pads PA-k of the second semiconductor chips 102 to 108.

### (Effects)

The pad PA-k will be explained as an example. In the seventh embodiment, the bonding wire 29 is connected to the pad PA-k of the first semiconductor chip 101 and the plurality of pads PA-k of the second semiconductor chips 102 to 108. Only the output buffer circuit OB1 formed in the first semiconductor chip 101 is an output buffer circuit having a high protection element function. This is so because the output buffer circuit OB2 having a small pin capacitance is formed in each of the second semiconductor chips 102 to 108. This makes it possible to reduce the capacitance connected to the bonding wire 29 and input pad 30, and prevent a decrease in signal propagation speed.

Also, the output buffer circuit OB1 is formed in the first semiconductor chip 101 to which the data DT or the like is initially input from the input pad 30. On the other hand, no output buffer circuit OB1 is formed in any of the second semiconductor chips 102 to 108 to which the data DT or the like is input after the first semiconductor chip 101. However, the protection element function of the first semiconductor chip 101 to which a surge voltage is most strongly applied is increased. On the other hand, the protective element function of the second semiconductor chips 102 to 108 to which a surge voltage is not strongly applied can be low. Consequently, it is possible to sufficiently protect the semiconductor device 200 against a surge voltage, and provide a semiconductor device capable of a high-speed operation by preventing a decrease in signal propagation speed caused by the protection circuit.

### Modification of Second Semiconductor Chip

FIG. 16 is a circuit diagram showing a modification of the buffer unit BF-kL of the second semiconductor chips 102 to 108. Note that the same reference numerals as in the previous drawings denote the same parts in FIG. 16.

The buffer unit BF-kL shown in FIG. 16 is obtained by omitting the output buffer circuit group B1 from the buffer unit BF-k shown in FIG. 13. An output buffer circuit group B2 is the same as that shown in FIG. 13, so a repetitive explanation will be omitted. Also, the layout of a PMOS transistor OB2TP and NMOS transistor OB2TN is the same as that shown in FIG. 11, so a repetitive explanation will be omitted.

### (Effects)

The above modification can achieve the same effects as those of the seventh embodiment and the second modification of the sixth embodiment. The user can adjust the outputs of the second semiconductor chips 102 to 108 as well after the product is shipped. Accordingly, when the output buffer circuit OB2 having a small diffusion layer capacitance is used as an output buffer for adjustment, the user can adjust the output after the product is shipped. This makes it possible to provide a semiconductor device having a small pin capacitance.

### First Modification of Seventh Embodiment

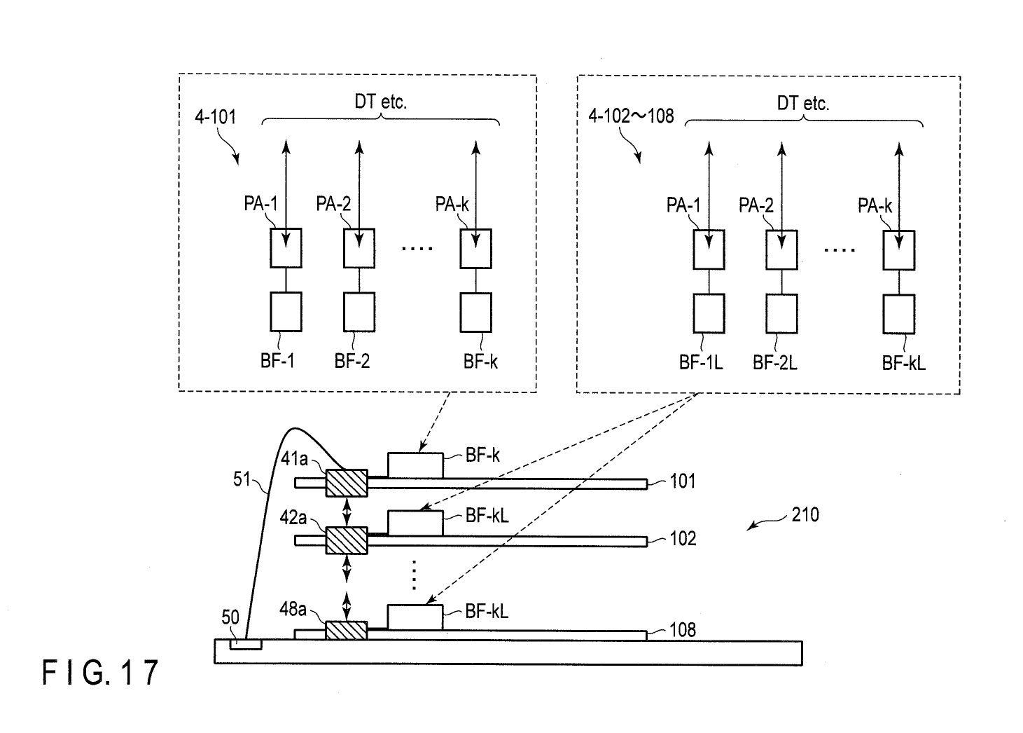

FIG. 17 shows an example of the first modification of the semiconductor device according to the seventh embodiment. A semiconductor device 210 shown in FIG. 17 is obtained by applying the semiconductor device 200 to the TSV system shown in FIG. 4. TSVs 41a to 48a are formed in a first semiconductor chip 101 and a plurality of second semiconductor chips 102 to 108 and electrically connected as they are brought into contact with each other, thereby stacking the first semiconductor chip 101 and the plurality of second semiconductor chips 102 to 108 on a base KD. The TSVs 41a to 48a are formed in portions corresponding to a pad PA-k of the first semiconductor chip 101 and pads PA-k of the second semiconductor chips 102 to 108. Also, the first semiconductor chip 101 is stacked in the uppermost layer.

In the above arrangement, the first semiconductor chip 101 and the plurality of second semiconductor chips 102 to 108 are sequentially stacked so as to overlap each other when viewed from above. Accordingly, the pads PA of the first semiconductor chip 101 and the plurality of second semiconductor chips 102 to 108 are electrically connected via the TSVs 48a to 41a.

In this state, the TSV 41a (pad PA-k) of the first semiconductor chip 101 and an input pad 50 are connected by a bonding wire 51.

### (Effects)

The above first modification can achieve the same effects as those of the seventh embodiment. In this modification, the pad PA-k of the first semiconductor chip 101 and the plurality of pads PA-k of the second semiconductor chips 102 to 108 are connected by the TSVs 48a to 41a. In this arrangement, only an output buffer circuit OB1 of the first semiconductor chip 101 is an output buffer circuit having a high protection element function. This is so because an output buffer circuit OB2 having a small pin capacitance is formed in each of the second semiconductor chips 102 to 108. This makes it possible to reduce the capacitance connected to the bonding wire 51 and input pad 50, and prevent a decrease in signal propagation speed.

Also, the output buffer circuit OB1 is formed in the first semiconductor chip 101 to which data DT and the like are initially input from the input pad 50. On the other hand, no output buffer circuit OB1 is formed in the second semiconductor chips 102 to 108 to which the data DT and the like are input after the first semiconductor chip 101. In this arrangement, the protection element function of the first semiconductor chip 101 to which a surge voltage is most strongly applied is increased. On the other hand, the protection element function of the second semiconductor chips 102 to 108 to which a surge voltage is not strongly applied can be low. Consequently, it is possible to sufficiently protect the semiconductor device 210 against a surge voltage, and provide a semiconductor device capable of a high-speed operation by preventing a decrease in signal propagation speed caused by the protection circuit.

In addition, the parasitic capacitance is small because the pads PA of the semiconductor chips are connected by the TSVs. Therefore, it is possible to largely increase the data communication speed.

Furthermore, the modification of the second semiconductor chip of the seventh embodiment described previously can be applied to the above-mentioned modification.

### Eighth Embodiment

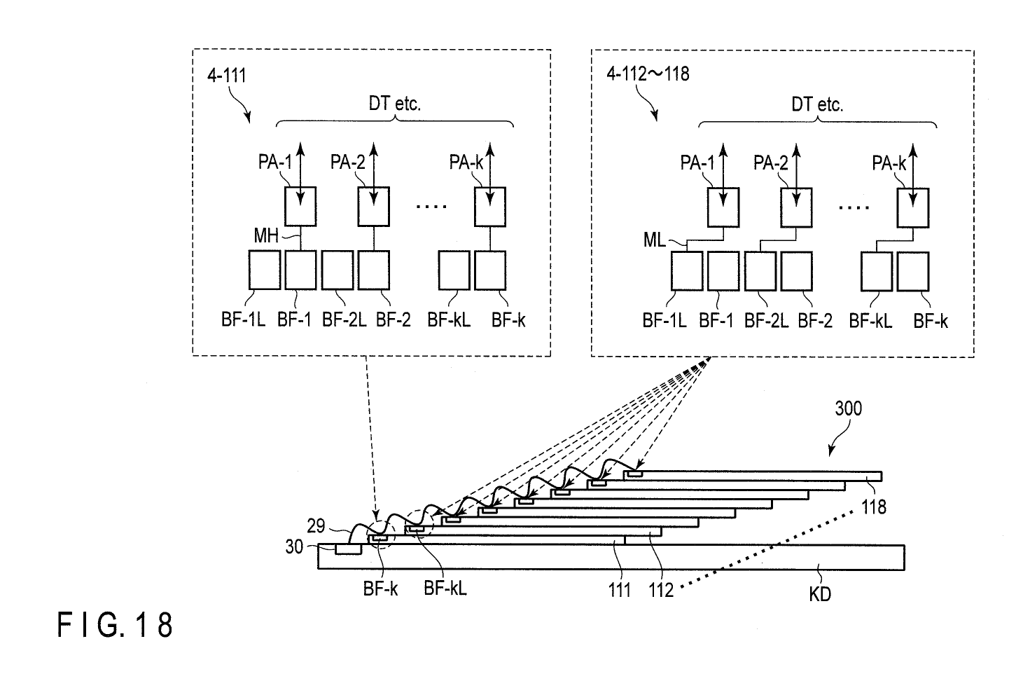

The eighth embodiment is directed to a semiconductor device in which a plurality of semiconductor chips having partially different metal interconnections are stacked. FIG. 18 shows an example of the semiconductor device according to the eighth embodiment.

In a semiconductor device 300 according to the eighth embodiment as shown in FIG. 18, a first semiconductor chip 111 placed on a base KD and a plurality of second semiconductor chips 112 to 118 are stacked as they are shifted from each other at a predetermined interval. The base KD has an input pin connection pad 30 to which an input pin is connected. The first semiconductor chip 111 and the plurality of second semiconductor chips 112 to 118 have the same size when viewed from above. Also, the first semiconductor chip 111 of the plurality of semiconductor chips is formed in the lowermost layer.

The first semiconductor chip 111 and second semiconductor chips 112 to 118 include buffer units BF1 to BFk and buffer units BF1L to BFkL. In the first semiconductor chip 111, pads PA-1 to PA-k are connected to the buffer units BF1 to BFk by metal interconnections MH. On the other hand, in the second semiconductor chips 112 to 118, pads PA-1 to PA-k are connected to the buffer units BF1L to BFkL by metal interconnections ML.

The metal interconnections MH and ML are, e.g., the uppermost metal interconnections of the semiconductor chips. That is, the first semiconductor chip 111 and second semiconductor chips 112 to 118 have the same structure except for the layouts of the upmost metal interconnections.

Also, in the first semiconductor chip 111, the buffer units BF1 to BFk are functional, and the buffer units BF1L to BFkL are unfunctional. On the other hand, in the second semiconductor chips 112 to 118, the buffer units BF1L to BFkL are functional, and the buffer units BF1 to BFk are unfunctional.

The rest of the arrangement is the same as that of the seventh embodiment, so a repetitive explanation will be omitted.

### (Effects)

The eighth embodiment can achieve the same effects as those of the seventh embodiment. In addition, the first semiconductor chip 111 and second semiconductor chips 112 to 118 can be manufactured by only changing one metal interconnection layer. Consequently, the first semiconductor chip 111 and second semiconductor chips 112 to 118 have many portions in common, and this can raise the design efficiency and production efficiency.

Also, the modification of the second semiconductor chip of the seventh embodiment described earlier can be applied to the eighth embodiment.

### First Modification of Eighth Embodiment

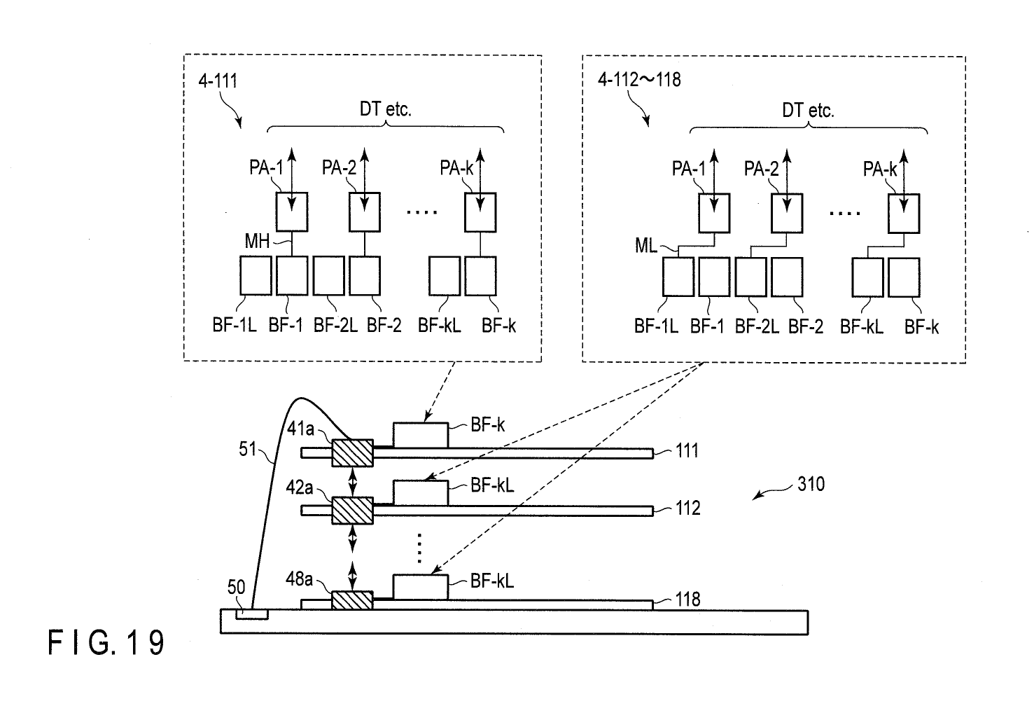

FIG. 19 shows the first modification of the semiconductor device according to the eighth embodiment. In FIG. 19, a semiconductor device 310 is obtained by applying the semiconductor device 300 to a so-called TSV system. As a consequence, the same effects as those of the eighth embodiment can be obtained. Also, the parasitic capacitance is small because pads PA of semiconductor chips are connected by TSVs. This makes it possible to largely increase the data communication speed.

It is also possible to apply the modification of the second semiconductor chip of the seventh embodiment to the first modification.

### Ninth Embodiment

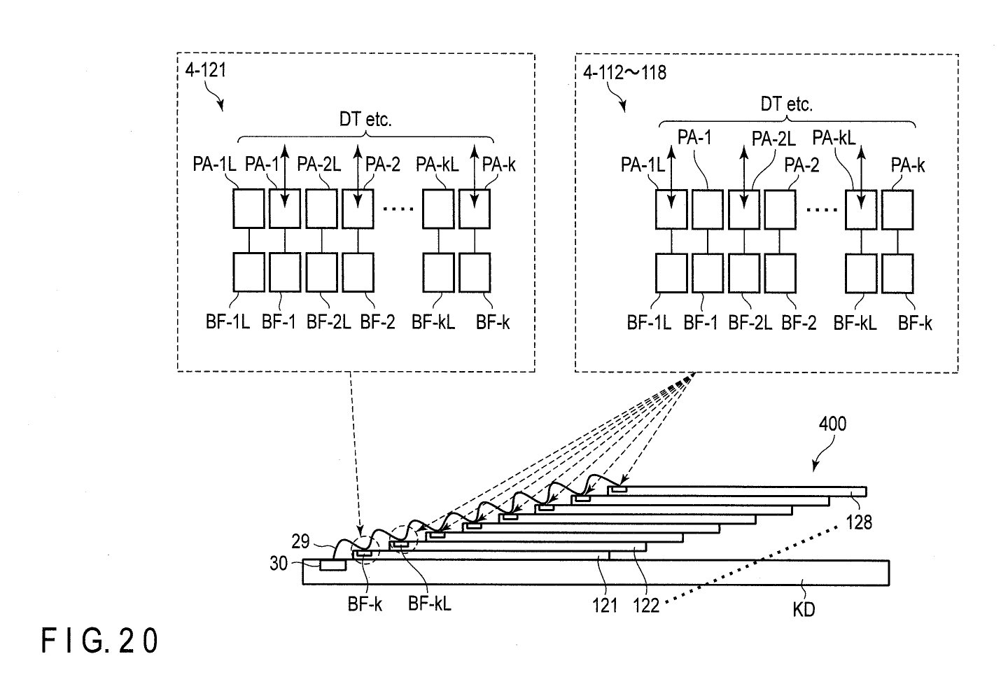

The ninth embodiment is directed to a semiconductor device in which semiconductor chips are stacked. FIG. 20 shows an example of the semiconductor device according to the ninth embodiment.

In a semiconductor device 400 according to the ninth embodiment as shown in FIG. 20, a first semiconductor chip 121 placed on a base KD and a plurality of second semiconductor chips 122 to 128 are stacked as they are shifted from each other at a predetermined interval. The base KD has an input pin connection pad 30 to which an input pin is connected. The first semiconductor chip 121 and the plurality of second semiconductor chips 122 to 128 have the same size when viewed from above. Also, the first semiconductor chip 121 of the plurality of semiconductor chips is formed in the lowermost layer.

The first semiconductor chip 121 and second semiconductor chips 122 to 128 have the same arrangement. That is, the first semiconductor chip 121 and second semiconductor chips 122 to 128 include pads PA-1 to PA-k connected to buffer units BF-1 to BF-k, and pads PA-1L to PA-kL connected to buffer units BF-1L to BF-kL.

As shown in FIG. 20, the first semiconductor chip 121 and second semiconductor chips 122 to 128 having the above arrangement are stacked as they are shifted from each other at a predetermined interval, thereby exposing the pads PA of these semiconductor chips. A bonding wire 29 is continuously sequentially bonded to the exposed pads PA.

The bonding wire 29 bonded to the input pad 30 is bonded to the pad PA-k of the first semiconductor chip 121, and bonded to the pads PA-kL of the second semiconductor chips 122 to 128. Thus, the input pad 30, the pad PA-k of the first semiconductor chip 121, and the pads PA-kL of the second semiconductor chips 122 to 128 are electrically connected.

Note that in the first semiconductor chip 121 and second semiconductor chips 122 to 128, the pads PA connected by the bonding wire 29 have the same function except for the buffer unit BF.

That is, a bonding word line is connected to the first semiconductor chip 121 so that the buffer unit BF-k functions, and a bonding wire is connected to the second semiconductor chips 122 to 128 so that the buffer units BF-kL function.

### (Effects)

The ninth embodiment can achieve the same effects as those of the seventh embodiment. In addition, the same effects as those of the seventh embodiment can be obtained by only changing the connection of the bonding wire 29. Consequently, it is possible to use identical semiconductor chips as the first semiconductor chip 121 and second semiconductor chips 122 to 128, and increase the design efficiency and production efficiency.

It is also possible to apply the modification of the second semiconductor chip of the seventh embodiment to this embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor chip including a first input pad, a first protection circuit, and a first internal circuit, the first input pad being connected to the first internal circuit and receiving an external signal, and the first protection circuit protecting the first internal circuit;
at least one second semiconductor chip including a second input pad, a second protection circuit, and a second internal circuit, the second input pad being connected to the second internal circuit and receiving the external signal, and the second protection circuit protecting the second internal circuit;
a first connector configured to electrically connect the first input pad and the second input pad; and
a second connector configured to connect the first protection circuit and first input pad of the first semiconductor chip,
wherein the second protection circuit of the at least one second semiconductor chip is not connected to the second input pad.

2. The device according to claim 1, further comprising:
a body, the first and second semiconductor chips being stacked on the body; and
a third input pad arranged on the body,
wherein the first input pad is connected to the third input pad by a third connector.

3. The device according to claim 1, wherein the first semiconductor chip and the second semiconductor chip are stacked, and the first connector is a through via.

4. The device according to claim 1, wherein the first semiconductor chip and the second semiconductor chip are stacked while being shifted from each other, and the first connector is a bonding wire.

5. A semiconductor device comprising:
a first semiconductor chip including a first input pad, a first protection circuit, a first internal circuit, and a third input pad, the first input pad being connected to the first internal circuit and receiving an external signal, and the third input pad being connected to the first protection circuit;
at least one second semiconductor chip including a second input pad, a second protection circuit, a second internal circuit, and a fourth input pad, the second input pad being connected to the second internal circuit and receiving the external signal, and the fourth input pad being connected to the second protection circuit; and
a first connector configured to electrically connect the first input pad and the second input pad,
wherein third connector connects the first input pad and the third input pad in the first semiconductor chip, and
the second input pad is not connected to the fourth input pad in the at least one second semiconductor chip.

6. The device according to claim 5, further comprising:
a body, the first and second semiconductor chips being stacked on the body; and
a fifth input pad arranged on the body, the fifth input pad being connected to an input pin,
wherein the first input pad and the first connector are electrically connected to the fifth input pad.

7. The device according to claim 5, wherein the first semiconductor chip and the second semiconductor chip are stacked, and the first connector is a through via.

8. The device according to claim 5, wherein the first semiconductor chip and the second semiconductor chip are stacked while being shifted from each other, and the first connector is a bonding wire.

9. A semiconductor device comprising:
a first semiconductor chip including a first input pad and a first protection circuit, the first input pad being connected to the first protection circuit and receiving an external signal; and
at least one second semiconductor chip including a second input pad, an internal circuit, and a second protection circuit, the second input pad being connected to the internal circuit, and the second protection circuit being connected to the second input pad and having protection performance lower than that of the first protection circuit,
wherein the first input pad of the first semiconductor chip and the second input pad of the second semiconductor chip are electrically connected by a first connector.

10. The device according to claim 9, further comprising:
a body, the first and second semiconductor chips being stacked on the body; and
a third input pad arranged on the body,
wherein the first input pad is connected to the third input pad by a second connector.

11. The device according to claim 10, wherein the first connector and the second connector are through vias.

12. The device according to claim 10, wherein
the first semiconductor chip includes a controller configured to control the at least one second semiconductor chip, and
the third input pad is connected to the first input pad, and connected to the second input pad via the controller.

13. A semiconductor device comprising:
a pad connected to a first node;
a first output buffer circuit including a first transistor having one terminal connected to the first node, the first transistor including a first gate and a first source/drain regions;
a second node electrically connected to the first node; and
a second output buffer circuit including a second transistor having one terminal electrically connected to the second node, the second transistor including a second gate and a second source/drain regions,
wherein a distance from a contact of the second source/drain region to the second gate of the second transistor is shorter than a distance from a contact of the first source/drain region to the first gate of the first transistor.

14. The device according to claim 13, further comprising:
a third node electrically connected to the first node;
a third transistor formed in the first output buffer and connected to the first node; and
a fourth transistor formed in the second output buffer and connected to the third node,
wherein the first transistor and the second transistor are p-type transistors, the third transistor and the fourth transistor are n-type transistors, the other terminal of each of the first transistor and the second transistor is connected to a power supply voltage, and the other terminal of each of the third transistor and the fourth transistor is connected to a ground voltage.

15. The device according to claim 13, further comprising a resistance formed in at least one of a portion between the first node and the second node, and a portion between the first node and the third node.

16. The device according to claim 13, further comprising an input buffer connected to the first node.

17. The device according to claim 13, wherein two or more the first output buffers are disposed, and two or more the second output buffers are disposed.
